(19) United States
(12) Patent Application Publication
(10) Pub. No.: US 2016/0336482 A1
(43) Pub. Date: Nov. 17, 2016

(54) LIGHT-EMITTING DEVICE

(71) Applicant: EPISTAR CORPORATION, Hsinchu (TW)

(72) Inventors: Shao-Ping Lu, Hsinchu (TW); Cheng-Feng Yu, Hsinchu (TW); Wen-Luh Liao, Hsinchu (TW); Hsin-Chan Chung, Hsinchu (TW); Shih-Chang Lee, Hsinchu (TW); Chih-Chiang Lu, Hsinchu (TW)

(21) Appl. No.: 14/709,985

(22) Filed: May 12, 2015

(51) Int. Cl. H01L 33/08; H01L 33/10; H01L 33/22

(52) U.S. Cl. CPC H01L 33/08; H01L 33/22; H01L 33/10

(57) ABSTRACT

An object of the present invention is to provide a light-emitting device comprising: a substrate, a first light-emitting semiconductor stack having a first transverse width, the first light-emitting semiconductor stack comprising a first active layer emitting a first radiation of a first dominant wavelength during operation; a second light-emitting semiconductor stack having a second transverse width less than the first transverse width and comprising a second active layer emitting a second radiation of a second dominant wavelength shorter than the first dominant wavelength during operation; and a first conductive connecting structure between the first light-emitting semiconductor stack and the second light-emitting semiconductor stack, wherein the first conductive connecting structure is lattice-mismatched to the first active layer and to the second active layer, the first light-emitting semiconductor stack is between the substrate and the second light-emitting semiconductor stack.

### TECHNICAL FIELD

The present application generally relates to a light-emitting device, and more particularly to a monolithic semiconductor light-emitting device comprising multiple dominant wavelengths.

### BACKGROUND

Light-emitting diodes (LEDs) are widely used as solid-state light sources. Compared to conventional incandescent light lamps or fluorescent light tubes, light-emitting diodes have advantages such as lower power consumption and longer lifetime, and therefore they gradually replace the conventional light sources and are applied to various fields such as traffic lights, back light modules, street lighting, and biomedical device.

### SUMMARY

An object of the present invention is to provide a light-emitting device comprising: a substrate, a first light-emitting semiconductor stack having a first transverse width, the first light-emitting semiconductor stack comprising a first active layer emitting a first radiation of a first dominant wavelength during operation; a second light-emitting semiconductor stack having a second transverse width less than the first transverse width and comprising a second active layer emitting a second radiation of a second dominant wavelength shorter than the first dominant wavelength during operation; and a first conductive connecting structure between the first light-emitting semiconductor stack and the second light-emitting semiconductor stack, wherein the first conductive connecting structure is lattice-mismatched to the first active layer and to the second active layer, the first light-emitting semiconductor stack is between the substrate and the second light-emitting semiconductor stack.

### BRIEF DESCRIPTION OF THE DRAWINGS

The foregoing aspects and many of the attendant advantages of this application will become more readily appreciated as the same becomes better understood by reference to the following detailed description, when taken in conjunction with the accompanying drawings, wherein:

FIG. 1 is a top view of a light-emitting device in accordance with the first embodiment of the present application;

FIG. 2A is a cross-sectional diagram along an A-A′ line of one example of the first embodiment of the light-emitting device in FIG. 1;

FIG. 2B is a cross-sectional diagram of another example of the first embodiment of the light-emitting device in FIG. 1;

FIG. 3A is one example of a top-view of the pattern of the third refractive layer of the first embodiment of the light-emitting device in FIG. 2A or FIG. 2B;

FIG. 3B is another example of a top-view of the pattern of the third refractive layer of the first embodiment of the light-emitting device in FIG. 2A or FIG. 2B;

FIGS. 4A to 4H demonstrate other examples of top views of the light-emitting devices in accordance with the first embodiment of the present application;

FIG. 5 is a cross-sectional diagram of a light-emitting device in accordance with the second embodiment of the light-emitting device of the present application;

FIG. 6 is a top view of a light-emitting device in accordance with the third embodiment of the light-emitting device of the present application;

FIG. 7 is a cross-sectional diagram along a B-B′ line of the light-emitting device in accordance with one the third embodiment of the present application in FIG. 6;

FIG. 8 is a top-view of the pattern of the third refractive layer of the light-emitting device in accordance with the third embodiment in FIG. 7;

FIGS. 9 to 14 demonstrate a manufacturing process for fabricating the light-emitting device shown in FIG. 7;

FIG. 15 is a top view of a light-emitting device in accordance with the fourth embodiment of the present application;

FIG. 16 is a cross-sectional diagram along a C-C′ line of the fourth embodiment of the light-emitting device in FIG. 15;

FIGS. 17 to 20 demonstrate a manufacturing process for fabricating the light-emitting device shown in FIG. 16;

FIG. 21 is a top view of a light-emitting device in accordance with the fifth embodiment of the present application;

FIG. 22 is a cross-sectional diagram along a D-D′ line of the light-emitting device in FIG. 21 in accordance with the fifth embodiment;

FIG. 23 is a top view of the pattern of the first conductive connecting structure on the lower current spreading oxide layer of the light-emitting device in accordance with the fifth embodiment in FIG. 22;

FIGS. 24 to 28 demonstrate a manufacturing process or fabricating the light-emitting device shown in FIG. 22;

FIG. 29 is a cross-sectional diagram of a light-emitting device in accordance with the sixth embodiment of the present application;

FIG. 30 is a cross-sectional diagram of a light-emitting device in accordance with the seventh embodiment of the present application; and

FIG. 31 is an exploded view of a light bulb in accordance with the present application.

### DETAILED DESCRIPTION OF THE PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precisely scaled and components may be exaggerated in view of width, height, length, etc. Herein, the similar or identical reference numerals will denote the similar or identical components throughout the drawings.

In the present application, if not specifically mention, the general expression of AlGaAs means AlₓGa₍₁₋ₓ₎As, wherein 0≦x≦1; the general expression of AlInP means AlₓIn₍₁₋ₓ₎P, wherein 0≦x≦1; the general expression of AlGaInP means (Al_{y}Ga_{(1-y)})₁₋ₓInₓ P, wherein 0≦x≦1, 0≦y≦1; and the general expression of InGaP means InₓGa₁₋ₓP, wherein 0≦x≦1. The content of the element can be adjusted for different purposes, such as matching the lattice constant of the growth substrate or adjusting the dominant wavelength.

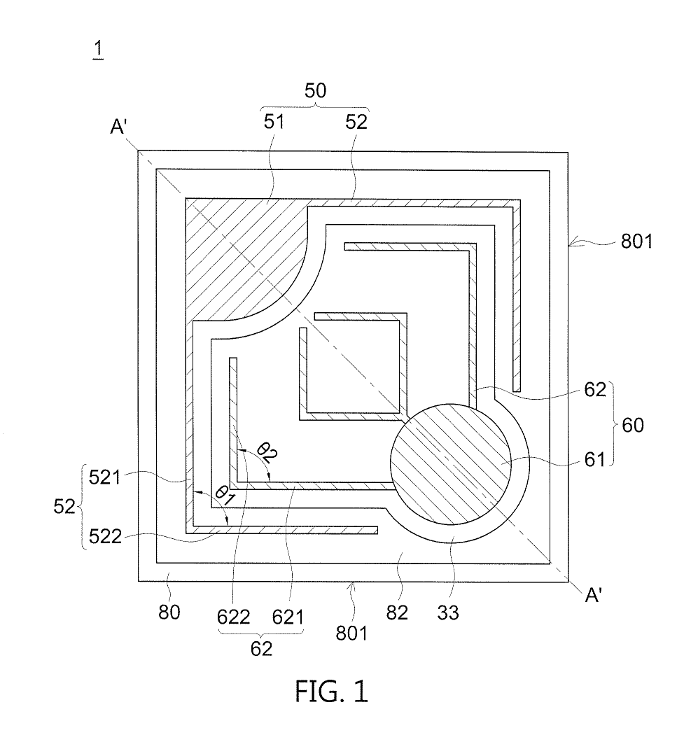

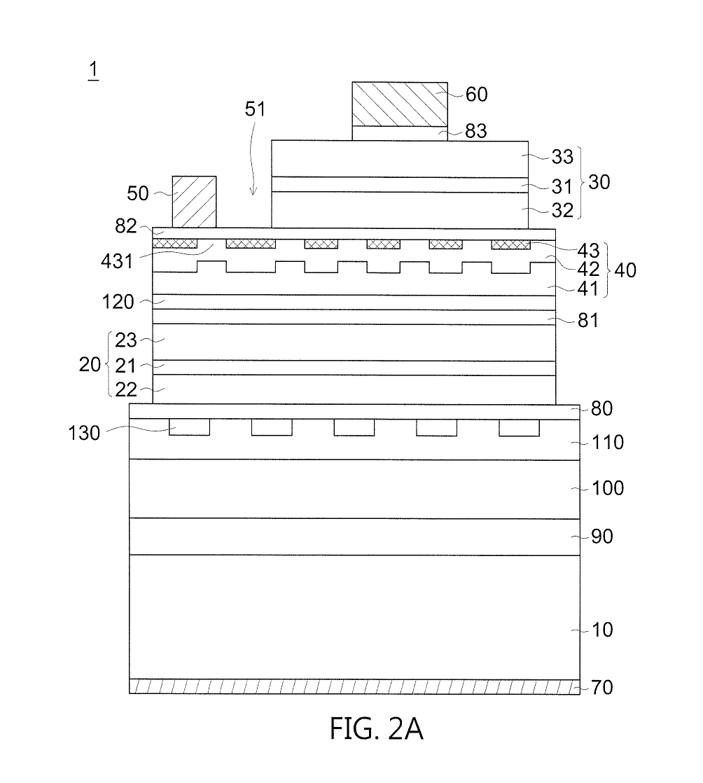

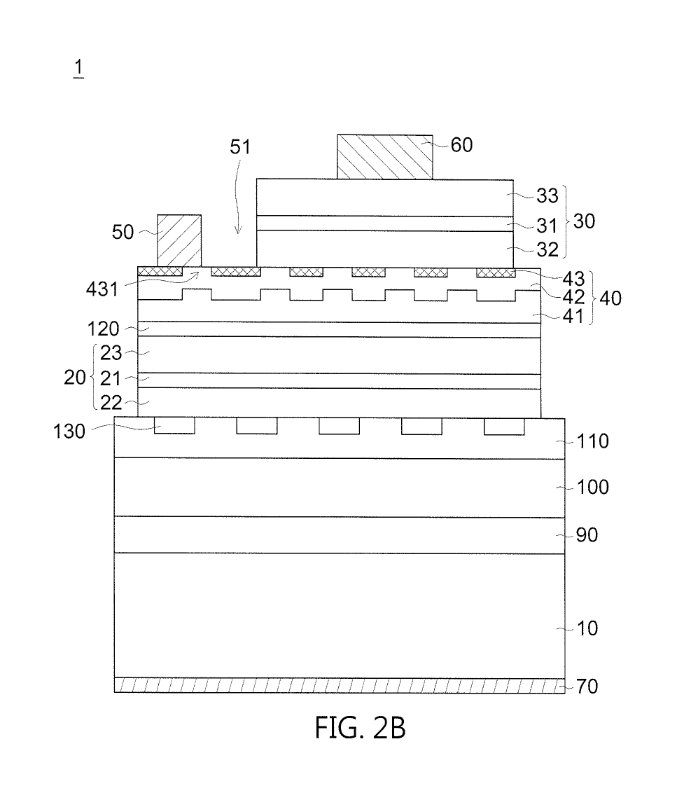

FIG. 1 is a top view of a light-emitting device in accordance with the first embodiment of the present application; FIG. 2A is a cross-sectional diagram along an A-A′ line of one example of the first embodiment of the light-emitting device in FIG. 1. The light-emitting device 1 comprises a substrate 10, a first light-emitting semiconductor stack 20 on the substrate 10, a second light-emitting semiconductor stack 30 on the first light-emitting semiconductor stack 20; a first conductive connecting structure 40 between the first light-emitting semiconductor stack 20 and the second light-emitting semiconductor stack 30, a first electrode 50 on the first conductive connecting structure 40, a second electrode 60 on the second light-emitting semiconductor stack 30, and a third electrode 70 on a surface of the substrate 10 opposite to the second light-emitting semiconductor stack 30. The first light-emitting semiconductor stack 20 has a first transverse width, and the second light-emitting semiconductor stack 30 has a second transverse width less than the first transverse width such that there is a region 51 on the first light-emitting semiconductor stack 20, wherein the region 51 is devoid of the second light-emitting semiconductor stack 30. The first electrode 50 is formed in the region 51.

The first light-emitting semiconductor stack 20 comprises a first active layer 21 emitting a first radiation of a first dominant wavelength during operation. The second light-emitting semiconductor stack 30 comprises a second active layer 31 emitting a second radiation of a second dominant wavelength shorter than the first dominant wavelength during operation. Preferably, the first dominant wavelength is in the invisible wavelength range, and more preferably, the first dominant wavelength is between 790 nm and 1500 nm both inclusive. The second dominant wavelength is in the visible wavelength region, and more preferably, the second dominant wavelength is between 620 nm and 790 nm. The first active layer 21 and the second active layer 31 are arranged in an order such that the first active layer 21 emitting the first radiation with longer dominant wavelength is closer to the substrate 10 than the second active layer 31. The first conductive connecting structure 40 is lattice-mismatched to the first active layer 21 and the second active layer 31 individually. Specifically, the first conductive connecting structure 40 electrically connects the first light-emitting semiconductor stack 20 and the second light-emitting semiconductor stack 30 simultaneously. Preferably, the first conductive connecting structure 40 is formed by evaporation or sputtering. In one embodiment, the growth substrate on which the first light-emitting semiconductor stack 20 is originally grown is different from the growth substrate on which the second light-emitting semiconductor stack 30 is originally grown.

In the present embodiment, the first light-emitting semiconductor stack 20 further comprises a first cladding layer 22 and a second cladding layer 23 sandwiching the first active layer 21. The band gap of the first cladding layer 22 and the band gap of the first cladding layer 22 are both higher than the band gap of the first active layer 21 for confining electrons or holes within the first active layer 21. The conductivity type, and/or the dopant of the first cladding layer 22 are different from that of the second cladding layer 23. In the present embodiment, the first cladding layer 22 comprises an n-type semiconductor for providing electrons. The second cladding layer 23 comprises a p-type semiconductor for providing holes. The second light-emitting semiconductor stack 30 further comprises a third cladding layer 32 and a fourth cladding layer 33 sandwiching the second active layer 31. The band gap of the third cladding layer 32 and the band gap of the fourth cladding layer 33 are both higher than the band gap of the second active layer 31 for confining electrons or holes within the second active layer 31. The conductivity type, and/or the dopant of the third cladding layer 32 are different from that of the fourth cladding layer 33. In the present embodiment, the third cladding layer 32 comprises a p-type semiconductor for providing electrons. The fourth cladding layer 33 comprises an n-type semiconductor for providing holes. Preferably, the second cladding layer 23 of the first light-emitting semiconductor stack 20, which is closer to the first conductive connecting structure 40 than the first cladding layer 22, is of the same conductivity type as the third cladding layer 32, which is closer to the first conductive connecting structure 40 than the fourth cladding layer 33 of the second light-emitting semiconductor stack 30. The first, the second, the third and the fourth cladding layer 22,23,32,33 comprise a Group III-V semiconductor material, such as AlInP, AlGaInP or AlGaAs. The n-type dopant can be Si or Te. The p type dopant can be C, Zn or Mg.

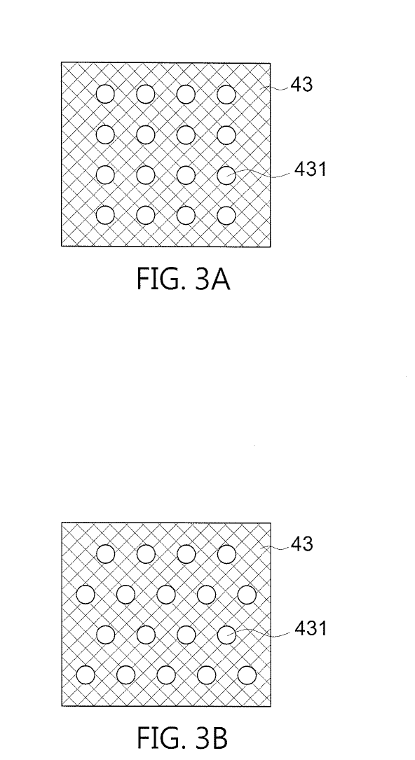

The first conductive connecting structure 40 has a third transverse width substantially the same as the first transverse width. The first conductive connecting structure 40 comprises multiple layers, wherein at least one of the layers comprises transparent conducive material, and preferably, comprising transparent conducive oxide material. In the present embodiment, the first conductive connecting structure 40 comprises a first refractive layer 41, a second refractive layer 42 on the first refractive layer 41, and a third refractive layer 43 on the second refractive layer 42, wherein each refractive layer has a refractive index, and the refractive indices are different from one another. Furthermore, the refractive indices of the multiple layers are gradually decreased in a direction from the substrate 10 toward the second light-emitting semiconductor stack 30. That is, the refractive index of the first refractive layer 41 is greater than the refractive index of the second refractive layer 42, and the refractive index of the second refractive layer 42 is greater than the refractive index of the third refractive layer 43. Preferably, the difference of the refractive indices of the two adjacent layers is not less than 0.1, and preferably is not less than 0.2. The first refractive layer 41 has a thickness greater than 1000 nm, and more preferably, between 1000 nm and 2500 nm. Preferably, the first refractive layer 41 has a refractive index not less than 1.8, and more preferably, between 2 and 2.3. The first refractive layer 41 comprises transparent conducive oxide material, such as indium tin oxide (ITO), indium oxide (InO), tin oxide (SnO), cadmium tin oxide (CTO), antimony tin oxide (ATO), aluminium zinc oxide (AZO), zinc tin oxide (ZTO), gallium doped zinc oxide (GZO), tungsten doped indium oxide (IWO), zinc oxide (ZnO), indium zinc oxide (IZO). The third refractive layer 43 is between the first refractive layer 41 and the second light-emitting semiconductor stack 30 and comprises a pattern comprising multiple openings 431 that are regularly arranged in a two-dimensional array as shown in one example of FIG. 3A or another example of FIG. 3B. To be more specific by referring to FIG. 3A, the openings 431 can be arranged in a grid pattern and aligned with one another in adjacent columns or in adjacent rows. With reference to FIG. 3B, the openings 431 in adjacent columns or in adjacent rows are staggered. In one embodiment, the substrate 10 has a first area, the area of the multiple openings 431 are less than 35% of the first area, and preferably, between 3% and 30% of the first area both inclusive, and more preferably, between 10% and 30% of the first area both inclusive. The third refractive layer 43 has a thickness greater than 800 Å, and more preferably, less than 2000 Å. Preferably, the third refractive layer 43 has a refractive index less than 1.5. In one embodiment, the third refractive layer 43 has a refractive index between 1.35 and 1.48. The third refractive layer 43 comprises an insulating material comprising SiOₓ or MgFₓ. The second refractive layer 42 is between the first refractive layer 41 and the third refractive layer 43, conformably covers the third refractive layer 43 and filled in the plurality of openings 431 of the third refractive layer 43. The second refractive layer 42 has a thickness not less than 30 Å, and preferably, not greater than 2000 Å, and more preferably, not greater than 200 Å. Preferably, the second refractive layer 42 has a refractive index not less than 1.6. In one embodiment, the second refractive layer 42 has a refractive index between 1.6 and 2.2. The second refractive layer 42 comprises transparent conducive oxide material comprising indium tin oxide (ITO), indium oxide (InO), tin oxide (SnO), cadmium tin oxide (CTO), antimony tin oxide (ATO), aluminium zinc oxide (AZO), zinc tin oxide (ZTO), gallium doped zinc oxide (GZO), tungsten doped indium oxide (IWO), zinc oxide (ZnO), or indium zinc oxide (IZO). In one embodiment, the material of the first refractive layer 41 can be the same as the material of the second refractive layer 42 but with different refractive indices, for example, the first refractive layer 41 and the second refractive layer 42 both comprise ITO but are with different oxygen contents so as to have different refractive indices. In the present embodiment, the first refractive layer 41 comprises IZO with a refractive index of between about 2.1 and 2.3, the second refractive layer 42 comprises ITO with a refractive index of between about 1.9 and 2.1, and the third refractive layer 43 comprises MgFₓ with a refractive index of between about 1.35 and 1.45. The method for forming the first refractive layer 41 comprises sputtering. The method for forming the second refractive layer 42 comprises evaporation. The first conductive connecting structure 40 is commonly electrically conductive to the first light-emitting semiconductor stack 20 and the second light-emitting semiconductor stack 30.

The light-emitting device 1 further comprises a first contact layer 80 between the substrate 10 and the first cladding layer 22 such that the third electrode 70 is electrically connected to the first light-emitting semiconductor stack 20 through the first contact layer 80 for achieving ohmic behavior between the third electrode 70 and the first light-emitting semiconductor stack 20. In one embodiment, the light-emitting device 1 further comprises a second contact layer 81 between the second cladding layer 23 and the first conductive connecting structure 40 such that the first electrode 50 is commonly electrically connected to the first light-emitting semiconductor stack 20 through the second contact layer 81 for achieving ohmic behavior between the first electrode 50 and the first light-emitting semiconductor stack 20. In one embodiment, the light-emitting device 1 further comprises a third contact layer 82 between the first conductive connecting structure 40 and the third cladding layer 32 such that the first electrode 50 is electrically connected to the second light-emitting semiconductor stack 30 through the third contact layer 82 for achieving ohmic behavior between the first electrode 50 and the second light-emitting semiconductor stack 30. To be more specific, the second refractive layer 42 physically contacts the third contact layer 82 by extending into the plurality of openings 431 of the third refractive layer 43 as shown in FIG. 2A. In one embodiment, the light-emitting device 1 further comprises a fourth contact layer 83 between the fourth cladding layer 33 and the second electrode 60 such that the second electrode 60 is electrically connected to the second light-emitting semiconductor stack 30 through the fourth contact layer 83 for achieving ohmic behavior between the second electrode 60 and the second light-emitting semiconductor stack 30. Preferably, the second contact layer 81 and the third contact layer 82 are of the same conductivity type. In the present embodiment, the second contact layer 81 and the third contact layer 82 are p-type semiconductors. The first, second, third and fourth contact layers 80,81,82,83 are with high doping concentration, such as greater than 10¹⁸/cm³, and preferably, between 5*10¹⁸/cm³ and 5*10¹⁹/cm³ both inclusive. The material of the first, second, third and fourth contact layers 80,81,82,83 comprise a Group III-V semiconductor material, such as GaAs, AlGaAs, InGaP, GaP or AlGaInP. Preferably, the second contact layer 81 comprises a Group III-V semiconductor material the same as that of the third contact layer 82. In the present embodiment, the third contact layer 82 between the first conductive connecting structure 40 and the second light-emitting semiconductor stack 30 is a semiconductor layer nearest to and/or physically contacts the third refractive layer 43. The second contact layer 81 between the first conductive connecting structure 40 and the first light-emitting semiconductor stack 20 is a semiconductor layer nearest to the first refractive layer 41. The difference Δr₁ between the refractive index of the third contact layer 82 and the refractive index of the third refractive layer 43 is greater than the difference Δr₂ between the refractive index of the second cladding layer 23 and the refractive index of the first refractive layer 41. In one embodiment, Δr₁ is not less than 1.35. In one embodiment, Δr1 is not greater than 2. In one embodiment, Δr1 is between 1.5 and 1.8. In one embodiment, Δr2 is not less than 0.5. In one embodiment, Δr2 is between 0.6 and 1.3. Preferably, Δr1 is greater than Δr2 by at least 0.3. In one embodiment, Δr1 is greater than Δr2 by a value between 0.5 and 1. Because the first conductive connecting structure 40 comprises multiple layers with different refractive indices gradually decreased in a direction from the substrate 10 toward the second light-emitting semiconductor stack 30, most of the first radiation emitted from the first active layer 21 easily passes through the first conductive connecting structure 40 and thus can be extracted from the front side of the light-emitting device, and most of the second radiation would lead to total reflection and thus is reflected by the first conductive connecting structure 40 and then can be extracted from the front side of the light-emitting device as well. The front side of the light-emitting device 1 is the side where the second electrode 60 situates and is opposite to the rear side where the third electrode 70 situates. As a result, in the present embodiment, the first radiation and the second radiation both can be extracted from the front side of the light-emitting device by the first conductive connecting structure 40. In one embodiment, the first conductive connecting structure 40 only comprises the first refractive layer 41 and the third refractive layer 43 without having the second refractive layer 42 interposed therebetween.

FIG. 2B is a cross-sectional diagram of another example of the first embodiment of the light-emitting device in FIG. 1. In the present embodiment, the third cladding layer 32 between the first conductive connecting structure 40 and the second active layer 31 is a semiconductor layer nearest to and/or physically contact the third refractive layer 43. The second cladding layer 23 between the first conductive connecting structure 40 and the first active layer 21 is a semiconductor layer nearest to the first refractive layer 41. The difference Δr₁ between the refractive index of the third cladding layer 32 and the refractive index of the third refractive layer 43 is greater than the difference Δr₂ between the refractive index of the second cladding layer 23 and the refractive index of the first refractive layer 41. In one embodiment, Δr₁ is not less than 1.55. In one embodiment, Δr₁ not greater than 2.2. In one embodiment, Δr₁ is between 1.7 and 2. In one embodiment, Δr₂ is not less than 0.8. In one embodiment, Δr₂ is between 0.9 and 1.6. Preferably, Δr₁ is greater than Δr₂ by at least 0.3. In one embodiment, Δr₁ is greater than Δr₂ by a value between 0.5 and 1.1.

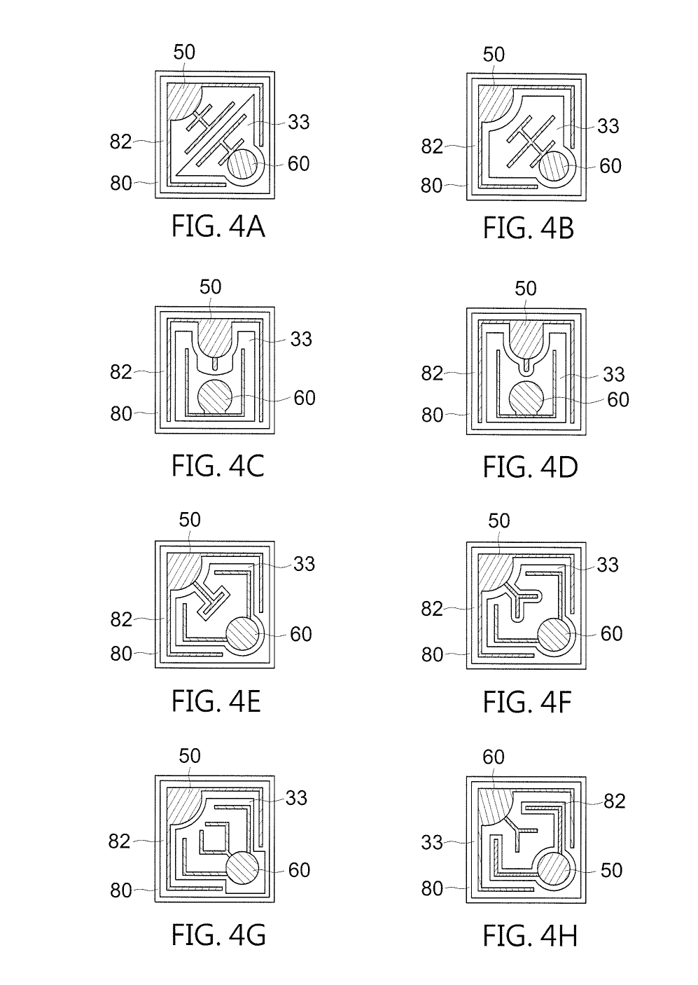

The first electrode 50, the second electrode 60, and the third electrode 70 are for electrically connected to an external power source for independently driving the first light-emitting semiconductor stack 20 and the second light-emitting semiconductor stack 30. In one embodiment, under a driving condition of the first electrode 50 being an anode and the second electrode 60 and the third electrode 70 both being cathodes, the first light-emitting semiconductor stack 20 is forward biased by the first electrode 50 and the third electrode 70; meanwhile, the second light-emitting semiconductor stack 30 is forward biased by the first electrode 50 and the second electrode 60. As a result, the first light-emitting semiconductor stack 20 and the second light-emitting semiconductor stack 30 can be independently controlled during operation; therefore the applied voltages across the first light-emitting semiconductor stack 20 and the second light-emitting semiconductor stack 30 can be different and independently controlled. Furthermore, the first electrode 50 is commonly electrically connected to the first light-emitting semiconductor stack 20 and the second light-emitting, semiconductor stack 30. The material of the first electrode 50, second electrode 60 and the third electrode 70 comprises transparent conductive material and/or metal material, wherein the transparent conductive material comprises transparent conductive oxide, and wherein the metal material includes Au, Pt, GeAuNi, Ti, BeAu, GeAu, Al, ZnAu. In the present embodiment, the first electrode 50 comprising a layer physically contacting the third contact layer 82 and comprising ZnAu. Referring to FIG. 1, the first electrode 50 comprises a first main part 51 and multiple first finger extensions 52. The second electrode 60 comprises a second main part 61 and multiple second finger extensions 62. The first main part 51 and the second main part 61 are arranged at diagonally opposite corners from the top view. The first finger extensions 52 extend from the first main part 51 toward the second main part 61 and are arranged at diagonally opposite corners. The second finger extensions 62 extend from the second main part 61 toward the first main part 51. In the present embodiment, each first finger extension 52 has a first part 521, a second part 522 connected to the first part 521, and an angle θ₁ between the first part 521 and the second part 522. Preferably, the angle θ₁ is between 80 to 100 degrees. In the present embodiment, the angle θ₁ is about 90 degrees. Besides, the first part 521 is substantially parallel to one of the sidewalls 801 of the light-emitting device 1, and the second part 522 is substantially parallel to another sidewall 801 of the light-emitting device 1. Each second finger extension 62 has a first part 621, a second part 622 connected to the first part 621, and an angle θ₂ between the first part 621 and the second part 622. Preferably, the angle θ₂ is between 80 to 100 degrees. In the present embodiment, the angle θ₂ is about 90 degrees. Besides, the first part 621 is substantially parallel to one of the sidewalls 801 of the light-emitting device 1, and the second part 622 is substantially parallel to another sidewall 801 of the light-emitting device 1. In the present embodiment, the number of the second finger extensions 62 is greater than the number of the first finger extensions 52. The arrangement of the first electrode 50 and the second electrode 60 shown in FIG. 1 can reach a better current spreading, and thus a better electrical and optical property of the light-emitting device 1 is obtained. FIGS. 4A to 4H demonstrate other examples of top views of the light-emitting device in accordance with the first embodiment of the present application. The first electrode 50 and the second electrode 60 can be arranged in different ways other than the way in FIG. 1 for obtaining desirable electrical and optical property of the light-emitting device 1.

In one embodiment, the light-emitting device 1 further comprises a second conductive connecting structure 90 between the substrate 10 and the first light-emitting semiconductor stack 20 for mechanically and electrically connecting the substrate 10 and the first light-emitting semiconductor stack 20. That is to say, the first conductive connecting structure 40 and the second conductive connecting structure 90 that are not grown from a growth substrate are disposed at two opposite sides of the first light-emitting semiconductor stack 20. The second conductive connecting structure 90 comprises transparent conducive material or metal material. The transparent conducive oxide material comprises indium tin oxide (ITO), indium oxide (InO), tin oxide (SnO), cadmium tin oxide (CTO), antimony tin oxide (ATO), aluminium zinc oxide (AZO), zinc tin oxide (ZTO), gallium doped zinc oxide (GZO), tungsten doped indium oxide (IWO), zinc oxide (ZnO), or indium zinc oxide (IZO). The metal material comprises In, Sn, Au, Ti, Ni, Pt, W or the alloys thereof.

In one embodiment, the light-emitting device 1 further comprises a reflector 100 between the second conductive connecting structure 90 and the first light-emitting semiconductor stack 20 for mainly reflecting the first radiation emitted from the first active layer 21 toward the front side of the light-emitting device 1. Besides, a minor amount of second radiation passing through the first conductive connecting structure 40 can also be reflected by the reflector 100 toward the front side of the light-emitting device. The reflector 100 is conductive for facilitating carriers flowing from the third electrode 70. The reflector 100 comprises a material with a reflectivity greater than 80% relative to the first dominant wavelength of the first radiation. Preferably, the reflector 100 comprises a material with a reflectivity greater than 80% relative to the first dominant wavelength of the first radiation and the second dominant wavelength of the second radiation both. Preferably, the reflector 100 comprises metal, such as Au, Ag, Al or the alloys thereof. The reflector 100 has a thickness of between about 2500 Å and 7500 Å.

In one embodiment, the light-emitting device 1 further comprises a first current spreading oxide layer 110 between the reflector 100 and the first contact layer 80 for better lateral current spreading. In one embodiment, the light-emitting device 1 further comprises a first transparent conductive layer 120 between the first conductive connecting structure 40 and the second contact layer 81. The first transparent conductive layer 120 further reduces the series resistance between the first electrode 50 and the first light-emitting semiconductor stack 20. The material of the first current spreading oxide layer 110 and the first transparent conductive layer 120 comprise transparent conductive oxide material comprising indium tin oxide (ITO), aluminum zinc oxide (AZO), SnCdO, antimony tin oxide (ATO), ZnO, Zn₂SnO₄ (ZTO) or indium zinc oxide (IZO), In the present embodiment, the first current spreading oxide layer 110 comprises IZO. The first transparent conductive layers 120 comprise ITO. The first transparent conductive layers 120 has a thickness not less than 30 Å, and preferably, not greater than 2000 Å, and more preferably, not greater than 500 Å. The difference Δr₁ between the refractive index of the third contact layer 82 and the refractive index of the third refractive layer 43 is greater than the difference Δr₂ between the refractive index of the second contact layer 81 and the refractive index of the first transparent conductive layer 120. In one embodiment, Δr₁ is not less than 1.35. In one embodiment, Δr₁ is not greater than 2. In one embodiment, Δr₁ is between 1.5 and 1.8. In one embodiment, Δr₂ is not less than 1.05. In one embodiment, Δr₂ is not greater than 1.7. In one embodiment, Δr₂ is between 1.2 and 1.5. Preferably, Δr₁ is greater than Δr₂ by at least 0.1. In one embodiment, Δr₁ is greater than Δr₂ by a value between 0.2 and 0.4.

In one embodiment, the substrate 10 is electrically conductive for conducting a current flowing between the first electrode 50 and the third electrode 70. The substrate 10 has a thickness thick enough for supporting the layers or structures thereon or preferably has a thickness greater than 100 microns (μm), and more preferably, less than 250 μm. The material of the substrate 10 comprises a conductive material. The material of the substrate 10 comprises Si, Ge, Cu, Al, Mo, Sn, Zn, Cd, Ni, Co, diamond like carbon (DLC), graphite, carbon fiber, metal matrix composite (MMC) or ceramic matrix composite (CMC).

In the present embodiment, the light-emitting device 1 further comprises a first ohmic contact layer 130 between the first contact layer 80 and the first current spreading oxide layer 110, wherein the first ohmic contact layer 130 comprises multiple contact dots that are regularly arranged in a two-dimensional array. The pattern of the first ohmic contact layer 130 can be the same as that of the first refractive layer 41 as shown in FIG. 3A and FIG. 3B. The first ohmic contact layer 130 forms an ohmic contact with the first contact layer 80. The first ohmic contact layer 130 comprises metal or metal alloy such as Au, GeAuNi, or GeAu.

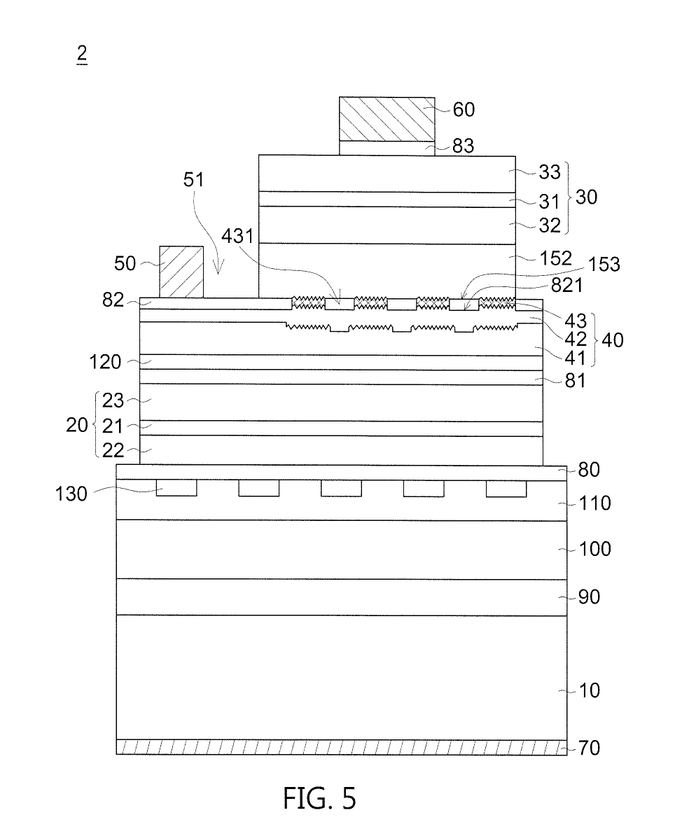

FIG. 5 is a cross-sectional diagram of a light-emitting device 2 in accordance with the second embodiment of the light-emitting device of the present application. The same reference number given or appeared in FIG. 5 has the same or equivalent meanings as mentioned in the foregoing embodiments in FIGS. 1 to 4. In the present embodiment, the light-emitting device 2 further comprises a current spreading semiconductor layer 152 between the third contact layer 82 and the third cladding layer 32 for improving current spreading throughout the second light-emitting semiconductor stack 30. Specifically, the current spreading semiconductor layer 152 has a band gap higher than the band gap of the second active layer 31 and the band gap of the first active layer 21 both, and the current spreading semiconductor layer 152 is substantially pervious to the first radiation emitted from the first active layer 21 and to the second radiation emitted from the second active layer 31. Preferably, the current spreading semiconductor layer 152 has a thickness preferably not less than 1 μm, and more preferably not greater than 10 μm. The current spreading semiconductor layer 152 comprises a surface 153 opposite to the second light-emitting semiconductor stack 30 and facing the first conductive connecting structure 40, wherein the surface 153 is roughened, or partially roughened. The roughened surface of the current spreading semiconductor layer 152 can improve the mechanical quality of the first conductive connecting structure 40, such as reducing air voids in the first conductive connecting structure 40 so as to improve the bonding strength of the conductive connecting structure 40. In one embodiment, the roughened part of the surface 153 is formed other than the area of the openings 431, and the other part of the surface 153 is substantially flat. In one embodiment, the roughened part is formed by lithographing and etching a portion of the third contact layer 82 and the current spreading semiconductor layer 152 to roughen the surface 153 of the current spreading semiconductor layer 152 after the step of forming the third contact layer 82 on the current spreading semiconductor layer 152. Because the roughness of the roughened part may be greater than the thickness of the third contact layer 82, for example, the roughness is between about 300 nm and 1000 nm while the thickness of the third contact layer 82 is between about 10 nm and 200 nm. Meanwhile, the third contact layer 82 comprises a substantially unetched surface interfacing with the second refractive layer 42. That is to say, the unetched surface 821 of the third contact layer 82 is substantially flat. As a result, the third contact layer 82 still forms an ohmic contact between the first electrode 50 and second light-emitting semiconductor stack 30 or between the first electrode 50 and the first light-emitting semiconductor stack 20. After forming the roughened part, the third refractive layer 43 and the second refractive layer 42 are conformally formed on the third contact layer 82 and the current spreading semiconductor layer 152. As a result, the part of the third refractive layer 43 aligning with the roughened part of the current spreading semiconductor layer 152 and the part of second refractive layer 42 aligning with the roughened part of the current spreading semiconductor layer 152 are also roughened. In the present embodiment, the second light-emitting semiconductor stack 30 is driven to emit the second radiation by conducting current between the first electrode 50 and the second electrode 60 through the third contact layer 82 and the second refractive layer 42. Preferably, the third refractive layer 43 is interposed between the first light-emitting semiconductor stack 20 and the second light-emitting semiconductor stack 30 and is not between the first electrode 50 and the first light-emitting semiconductor stack 20. The current spreading semiconductor layer 152 comprises a Group III-V semiconductor material, such as AlGaAs or GaP.

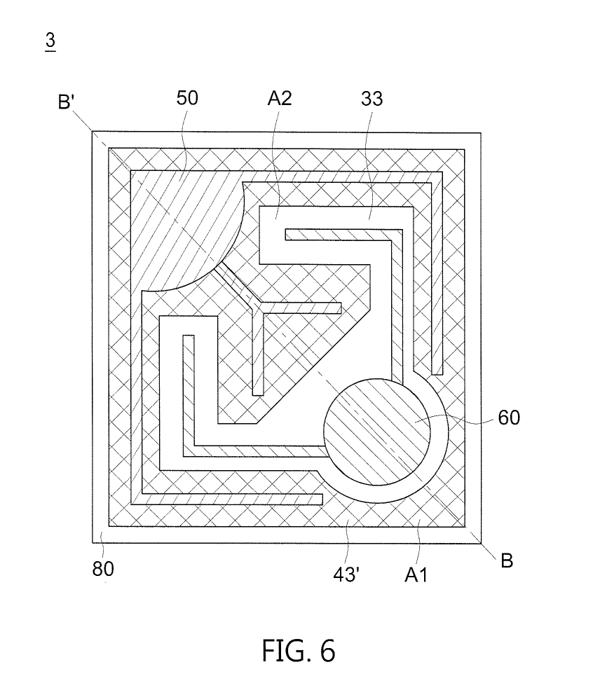

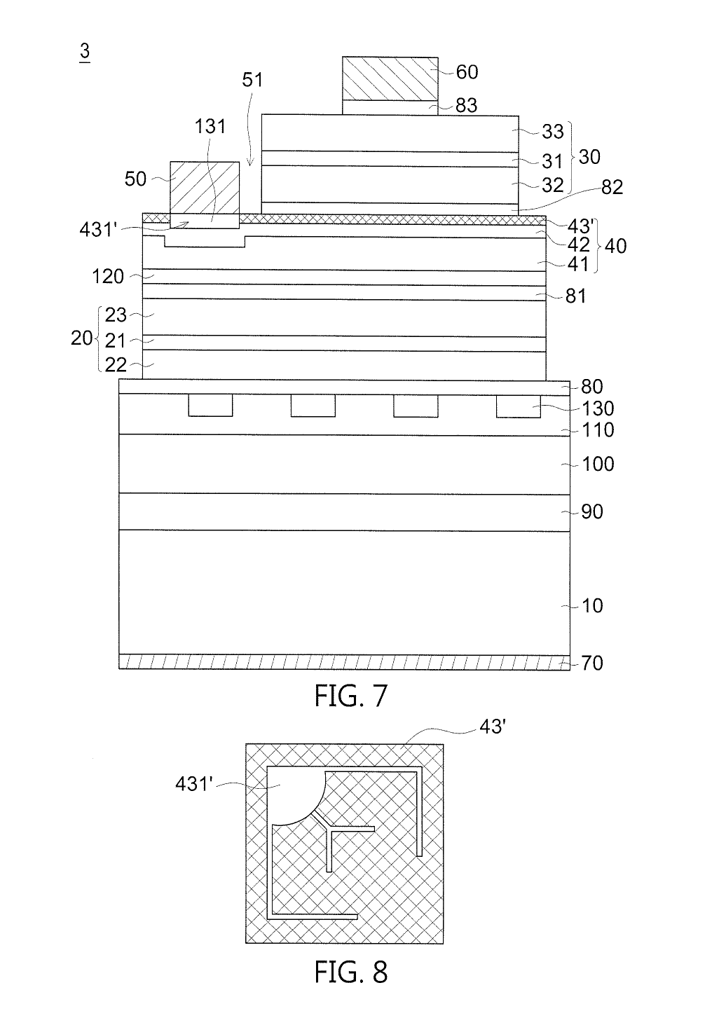

FIG. 6 is a top view of a light-emitting device in accordance with the third embodiment of the light-emitting device 3 of the present application; FIG. 7 is a cross-sectional diagram along a B-B′ line of the light-emitting device 3 in accordance with the third embodiment of the present application in FIG. 6. The same reference number given or appeared in FIG. 6 has the same or equivalent meanings as mentioned in the foregoing embodiments. In the present embodiment, the light-emitting device 3 further comprises a second ohmic contact layer 131 formed in the first conductive connecting structure 40. The region 51 is devoid of the third contact layer 82. The second ohmic contact layer 131 physically contacts the first electrode 50 and is electrically connected to the first electrode 50. The second ohmic contact layer 131 comprises a pattern having multiple extensions extending toward the second electrode 60. Specifically, the pattern of the second ohmic contact layer 131 is complementary to the pattern of the third refractive layer 43′. To be more specific, with reference to FIGS. 7 and 8, the opening 431′ of the third refractive layer 43′ comprises a contour substantially the same as the pattern of the second ohmic contact layer 131. As a result, the second ohmic contact layer 131 is filled in the opening 431′ of the third refractive layer 43′. The second refractive layer 42 conformably covers the third refractive layer 43′ and the second ohmic contact layer 131. The second ohmic contact layer 131 forms an ohmic contact with the third electrode 50 so as to reduce forward voltage of the light-emitting device 3. In one embodiment, the substrate 10 has a first area, and the second ohmic contact layer 131 has a second area of between about 3% and 25% both inclusive of the first area, and preferably, of between about 3% and 10% both inclusive of the first area. As a result, the second ohmic contact layer 131 not only forms an ohmic contact with the first electrode 50 but also reduces shielding the first radiation from emitting out of the light-emitting device 3. The second ohmic contact layer 131 comprises conductive material such as metal alloy comprising BeAu or ZnAu alloy. In the present embodiment, because the light-emitting device 3 comprises the second ohmic contact layer 131, the light-emitting device 2 is with lower forward voltage compared to the light-emitting device 1.

Referring to FIG. 6 and FIG. 7, the substrate 10 has a first area, the first light-emitting semiconductor stack 20 has a first exposed area A1 neither covered by the first electrode 50 nor covered by the fourth cladding layer 33. The second light-emitting semiconductor stack 30 has a second exposed area A2 not covered by the second electrode 60. The first exposed area A1 is of between about 20% and 60% of the first area, and preferably, between about 35% and 50% of the first area. The second exposed area A2 is of between about 15% and 50% of the first area, and preferably, between about 25% and 35% of the first area. Preferably, the first exposed area A1 is greater than the second exposed area A2. More preferably, the ratio of the first exposed area A1 to the second exposed area A2 is between about 1.1 and 3, and more preferably between 1.1 and 2.05. The area ranges or ratios set forth above are to compensate the difference between the luminous efficiencies of the first light-emitting semiconductor stack 20 and the second light-emitting semiconductor stack 20. Referring to FIGS. 4A to 4H, the first exposed area A1 (the exposed area of 82) and the second exposed area A2 (the exposed area of 33) can be arranged in different ways other than the way in FIG. 6 for obtaining desirable electrical and optical property of the light-emitting device.

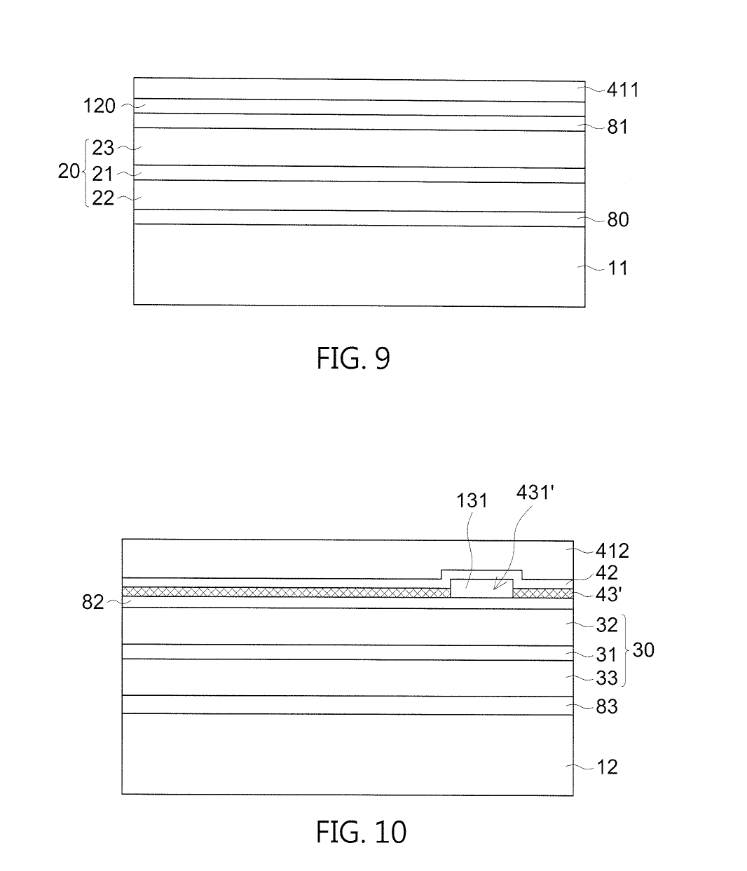

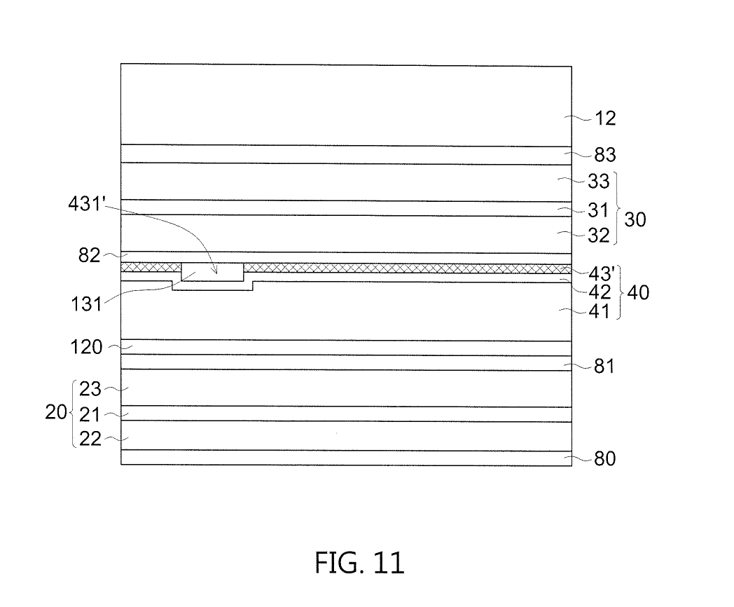

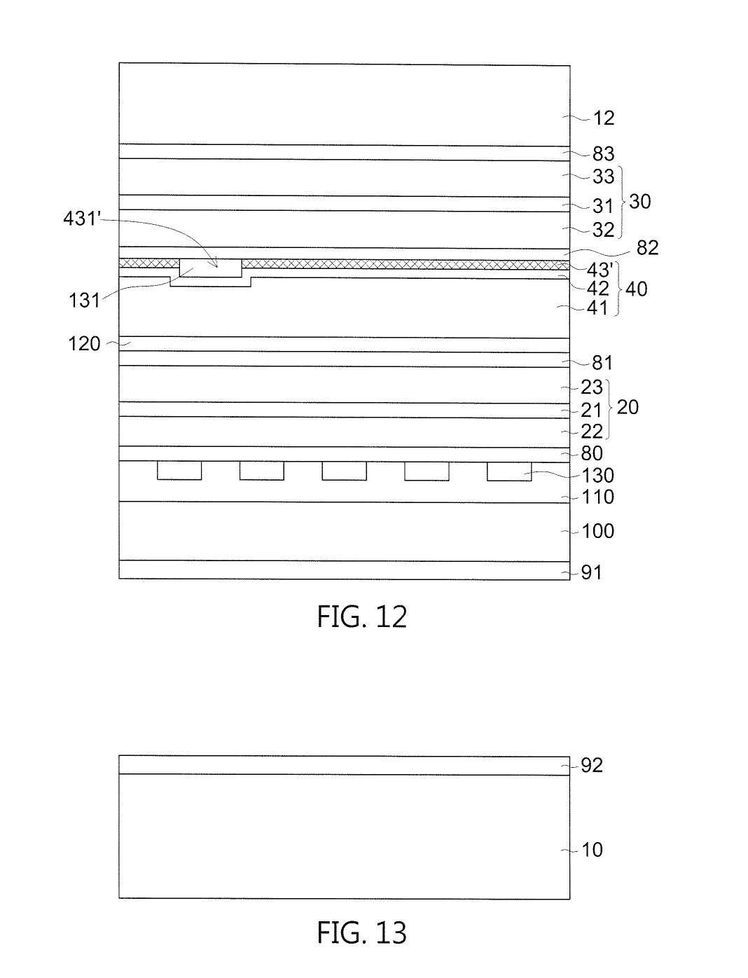

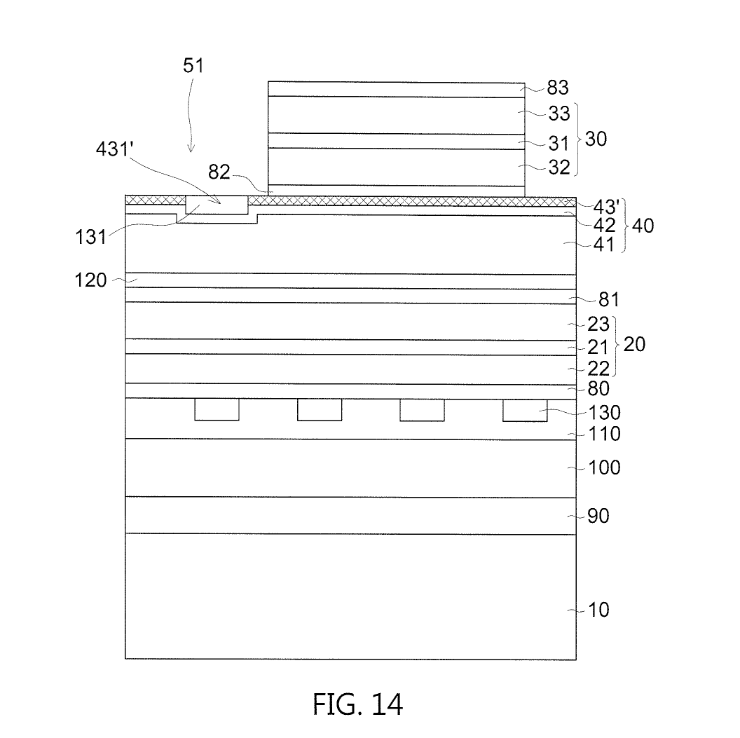

FIGS. 9 to 14 demonstrate a manufacturing process for fabricating the light-emitting device 3 shown in FIG. 7. Referring to FIG. 9, the method for making a light-emitting device 3 comprising the steps of: (i) providing a first growth substrate 11; (ii) sequentially growing a first contact layer 80, a first light-emitting semiconductor stack 20, a second contact layer 81 on the first growth substrate 11 by epitaxy method; and (iii) forming a first transparent conductive layer 120 on the second contact layer 81 and forming a first sub-bonding layer 411 comprising transparent conductive oxide on the first transparent conductive layer 120, wherein the first sub-bonding layer 411 has a thickness of between about 5000 Å and 1100 nm. In one embodiment, the upper surface of the first sub-bonding layer 411 opposite to the first growth substrate 11 can be roughened or textured to improve bonding quality during the bonding step afterwards. Referring to FIG. 10, the method further comprises steps of: (iv) providing a second growth substrate 12; (v) sequentially growing a fourth contact layer 83, a second light-emitting semiconductor stack 30, a third contact layer 82 on the second growth substrate 12 by epitaxy method; (vi) forming a patterned second ohmic contact layer 131 on the third contact layer 82; (vii) forming a third refractive layer 43′ on the third contact layer 82 and exposing the second ohmic contact layer 131; (ix) conformally forming the second refractive layer 42 on the second ohmic contact layer 131 and on the third refractive layer 43′ to cover the second ohmic contact layer 131 and the third refractive layer 43′; (x) forming a second sub-bonding layer 412 comprising transparent conductive oxide on the second refractive layer 42, wherein the second sub-bonding layer 412 has a thickness of between about 5000 Å and 1100 nm. In one embodiment, the upper surface of the second sub-bonding layer 412 opposite to the second growth substrate 12 can be roughened or textured to improve mechanical quality after the bonding step afterwards. Referring to FIG. 11, the method further comprises steps of: (xi) connecting the structures as shown in FIG. 9 and FIG. 10 by bonding the first sub-bonding layer 411 and the second sub-bonding layer 412 to form the first refractive layer 41; and (xii) removing the first growth substrate 11 after the bonding step. Referring to FIG. 12, the method further comprises steps of: (xiii) forming a first ohmic contact layer 130 on the first contact layer 80; (xiv) forming a first current spreading oxide layer 110 on the first ohmic contact layer 130 and covering the first ohmic contact layer 130; (xv) forming a reflector 100 on the first current spreading oxide layer 110; and (xvi) forming a third sub-bonding layer 91 comprising metal on the reflector 100. Referring to FIG. 13, the method further comprises steps of: (xvii) providing a substrate 10; (xviii) forming a fourth sub-bonding layer 92 comprising metal on the substrate 10, Referring to FIG. 14, the method further comprises steps of: (xix) connecting the structures as shown in FIG. 12 and FIG. 13 by bonding the third sub-bonding layer 91 and the fourth sub-bonding layer 92 to form the second conductive connecting structure 90; (xx) removing the second growth substrate 12 after the second bonding step; (xxi) removing a part of the second light-emitting semiconductor stack 30 and a part of the third contact layer 82 to form a region 51 exposing the second ohmic contact layer 131 and on the first light-emitting semiconductor stack 20; (xxii) forming the second electrode 60 on the fourth contact layer 83, forming the first electrode 50 in the region 51, and forming the third electrode 70 on the back side of the substrate 10 so as to obtain the light-emitting device 3 as shown in FIG. 7. The manufacturing process for fabricating the light-emitting device 3 comprises two bonding steps after forming the first light-emitting semiconductor stack 20 emitting the first radiation with longer dominant wavelength relative to the second dominant wavelength of the second radiation. The bonding steps are performed at two opposite sides of the first light-emitting semiconductor stack 20.

The first growth substrate 11 and the second growth substrate 12 comprises but is not limited to germanium (Ge), gallium arsenide (GaAs), indium phosphide (InP), gallium phosphide (GaP), sapphire, silicon carbide (SiC), silicon (Si), lithium aluminum oxide (LiAlO2), zinc oxide (ZnO), gallium nitride (GaN), aluminum nitride (AlN), glass, composite, diamond, CVD diamond, diamond-like carbon (DLC), and so on. Preferably, the first growth substrate 11 and the second growth substrate 12 both comprise GaAs.

The light-emitting device 1, 2 and 3 in accordance with the present application is a monolithic semiconductor light-emitting diode die comprising multiple active layers emitting multiple dominant wavelengths for integrating multiple functions into one light-emitting diode die. As a result, the volume of the light-emitting device is significantly reduced. Furthermore, because the light-emitting device is a monolithically single die featured with dual dominant wavelengths while independently driving the first active layer 21 and the second active layer 31, the light-emitting device of the present embodiment may be applicable in biomedical field as wearable devices such as pulse oximeters for monitoring blood oxygen saturation (SpO₂) and detecting hemoglobin by alternately or periodically driving the first light-emitting semiconductor stack 20 and the second light-emitting semiconductor stack 30. Additionally, because two different light-emitting semiconductor stacks are connected by a conductive connecting structure, there is no need to consider the lattice-mismatch issue between the materials of the light-emitting semiconductors. As a result, it is easier to make the light-emitting device comprising multiple light-emitting semiconductors with different materials. Furthermore, because the conductive connecting structure comprises multiple layers with different refractive indices gradually decreased in a direction from the substrate toward the second light-emitting semiconductor stack with shorter dominant wavelength relative to the first dominant wavelength, the conductive connecting structure facilitates the second radiation to be reflected and the first radiation to be passed through. As a result, the first radiation and the second radiation can be both extracted from the front side of the light-emitting device.

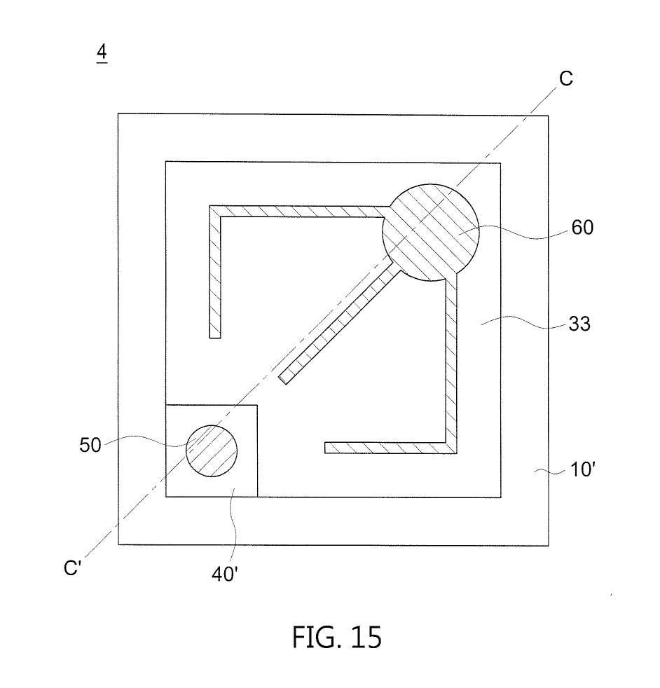

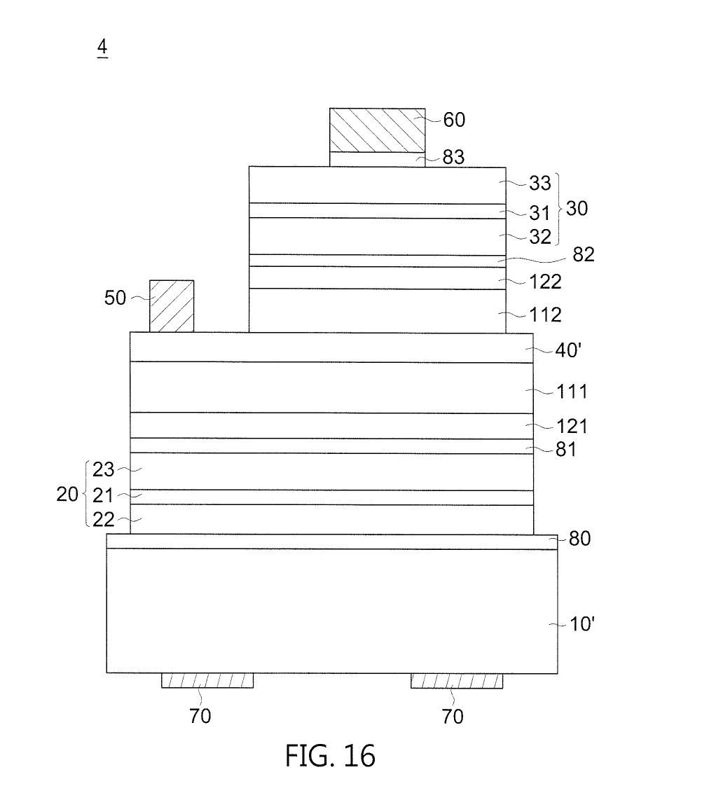

FIG. 15 is a top view of a light-emitting device 4 in accordance with the fourth embodiment of the present application; FIG. 16 is a cross-sectional diagram along a C-C line of the fourth embodiment of the light-emitting device 4 in FIG. 15. The same reference number given or appeared in FIG. 16 has the same or equivalent meanings as mentioned in the foregoing embodiments. In the present embodiment, the first conductive connecting structure 40′ comprises metal comprising Au, Sn, In, Pt, Ti, Ni W or the alloys thereof. Preferably, the first conductive connecting structure 40′ comprises Au. More preferably, the first conductive connecting structure 40′ serves as a bonding layer connecting the first light-emitting semiconductor stack 20 and the second light-emitting semiconductor stack 30 and also serves as a reflector having a reflectivity higher than 85% to both the first radiation and the second radiation so as to reflect the first radiation and the second radiation toward two opposite directions respectively. The light-emitting device 4 comprises a lower current spreading oxide layer 111 between the second contact layer 81 and the first conductive connecting structure 40′ for lateral current spreading. The light-emitting device 4 comprises a first transparent conductive layer 121 between the second contact layer 81 and the lower current spreading oxide layer 111 for reducing the series resistance between the first conductive connecting structure 40′ and the first light-emitting semiconductor stack 20. The light-emitting device 4 further comprises an upper current spreading oxide layer 112 between the third contact layer 82 and the first conductive connecting structure 40′ for spreading current laterally. The light-emitting device 4 comprises a second transparent conductive layer 122 between the third contact layer 82 and the upper current spreading oxide layer 112 for reducing the series resistance between the first conductive connecting structure 40 and the second light-emitting semiconductor stack 30. In one embodiment, the lower, upper current spreading oxide layers 111, 112 and the first, second transparent conductive layers 121, 122 comprise transparent conductive material, and preferably, comprise transparent conductive oxide, such as ITO. The substrate 10′ is the growth substrate on which the first light-emitting semiconductor stack 20 is originally grown, and preferably, the substrate 10′ comprises GaAs pervious to the first radiation. The third electrode 70 in the present embodiment is patterned such that the first radiation emitted from the first active layer 21 can escape from the rear side of the light-emitting device and the sidewalls of the substrate 10′.

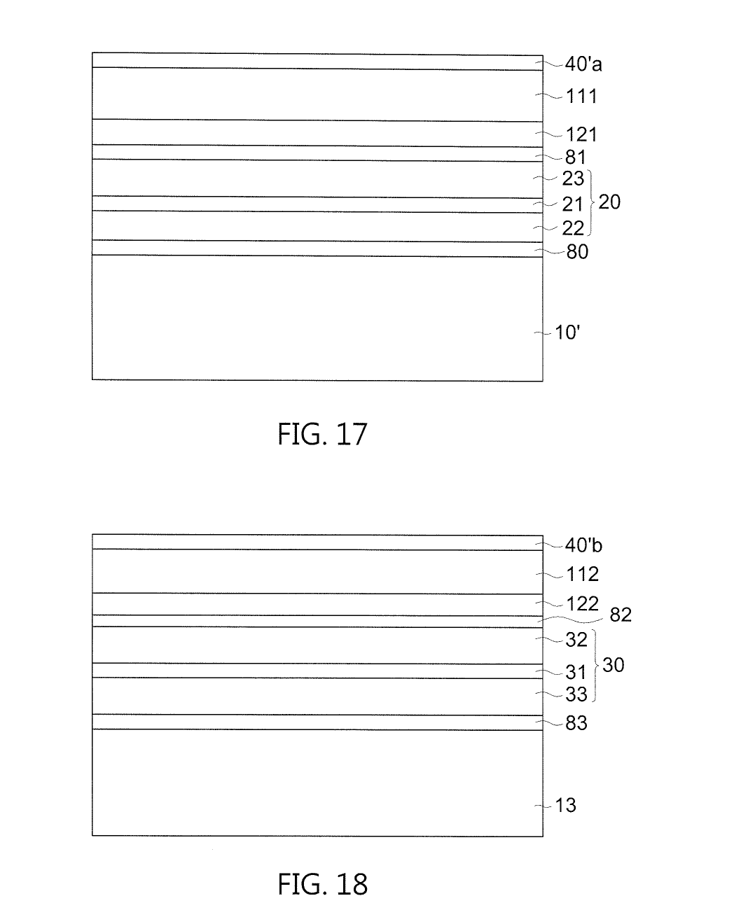

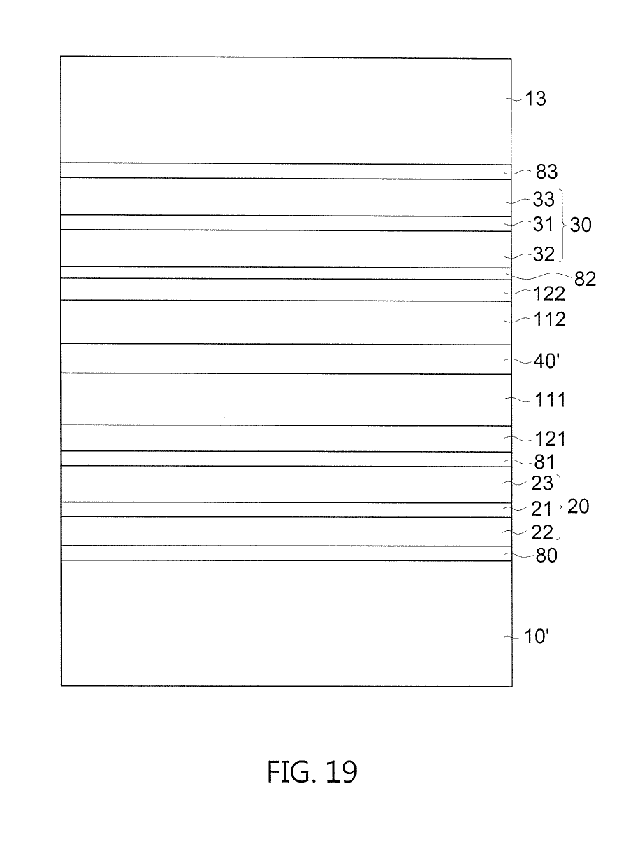

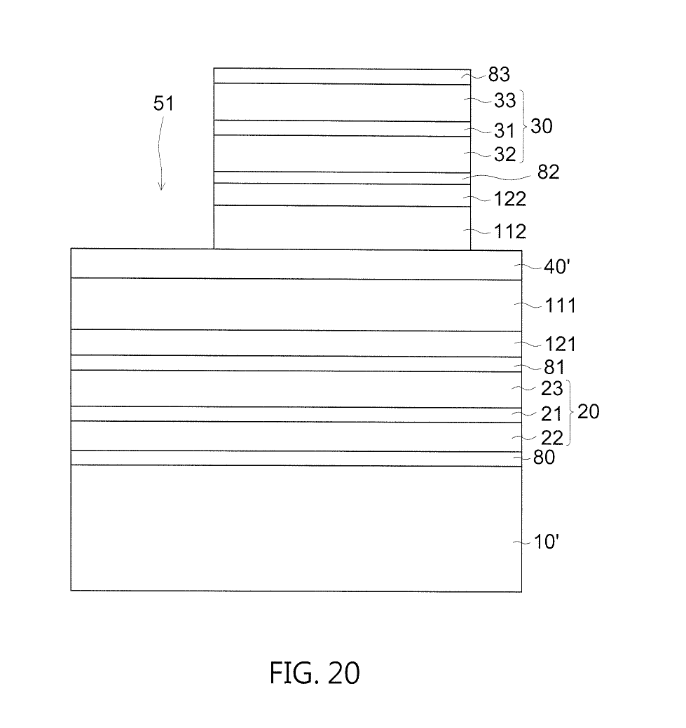

FIGS. 17 to 20 demonstrate a manufacturing process for fabricating the light-emitting device 4 shown in FIG. 16. Referring to FIG. 17, the method for making a light-emitting device 4 comprises steps of: (i) providing a growth substrate 10′; (ii) sequentially growing a first contact layer 80, a first light-emitting semiconductor stack 20, a second contact layer 81 by epitaxy method, and forming a first transparent conductive layer 121 and a lower current spreading oxide layer 111 on the growth substrate 10′; and (iii) forming a first sub-bonding layer 40′a on the lower current spreading oxide layer 111, wherein the first sub-bonding layer 40′a comprises metal, and the first sub-bonding layer 40′a has a thickness of between about 1000 nm and 3000 nm. Referring to FIG. 18, the method further comprises steps of: (iv) providing a growth substrate 13; (v) sequentially growing a fourth contact layer 83, a second light-emitting semiconductor stack 30, a third contact layer 82 by epitaxy method, and forming a second transparent conductive layer 122 and an upper current spreading oxide layer 112 on the third contact layer 82; and (vi) forming a second sub-bonding layer 40′b on the upper current spreading oxide layer 112, wherein the second sub-bonding layer 40′b comprises metal and has a thickness of between about 1000 and 3000 nm. Referring to FIG. 19, the method further comprises the steps of: (vii) connecting the structures as shown in FIG. 17 and FIG. 18 by bonding the first sub-bonding layer 40′a and the second sub-bonding layer 40′b to form the first conductive connecting structure 40′. Referring to FIG. 20, the method further comprises steps of: (viii) removing the growth substrate 13; removing a part of the second light-emitting semiconductor stack 30 to form a region 51 on the first light-emitting semiconductor stack 20 and exposing the first conductive connecting structure 40′; and (ix) forming the first electrode 50 in the region 51, forming the second electrode 60 on the fourth contact layer 83, and forming the third electrode 70 on the back side of the growth substrate 10′ so as to obtain the light-emitting device 4 as shown in FIG. 16.

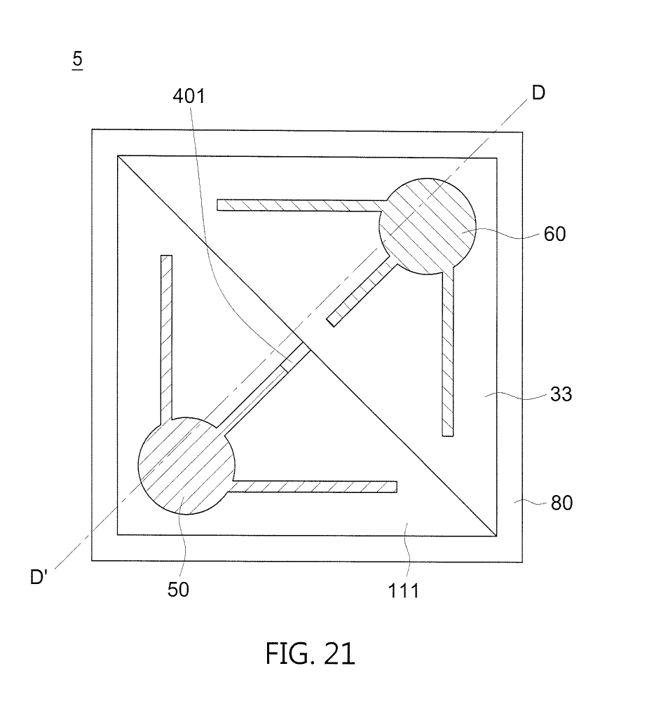

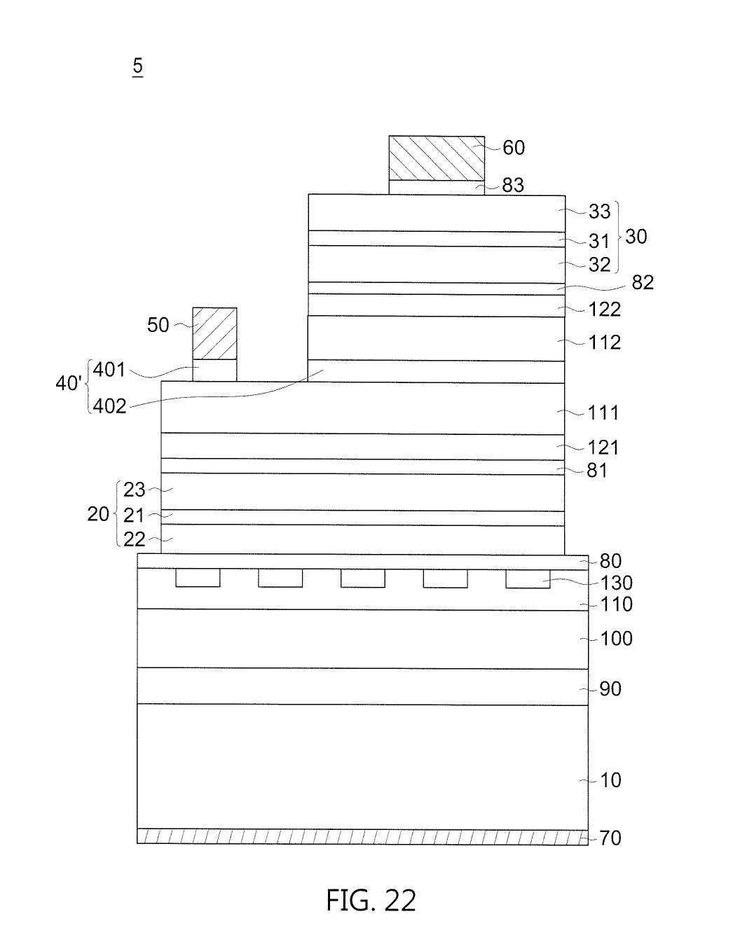

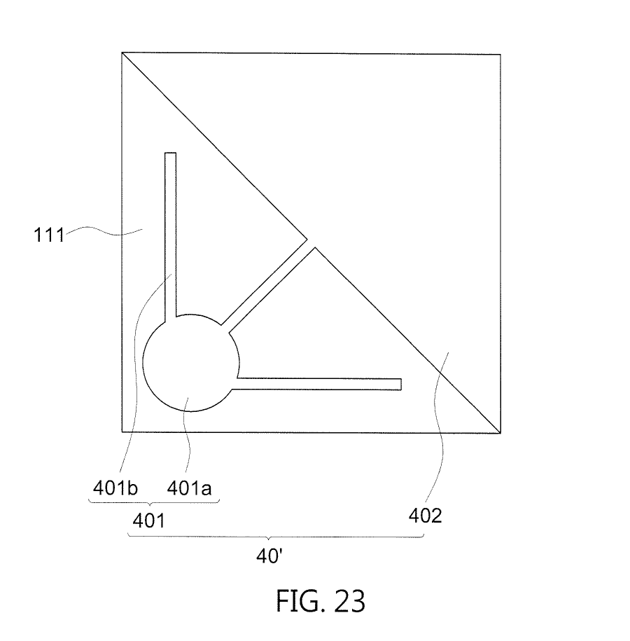

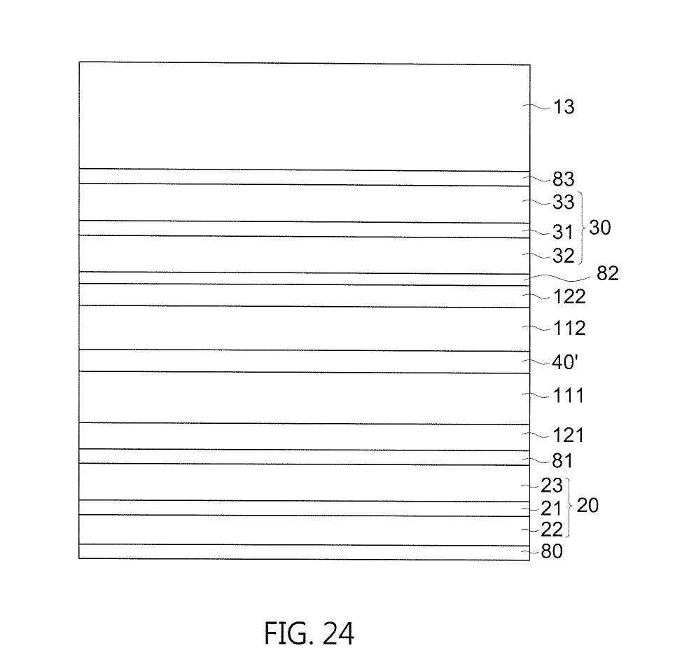

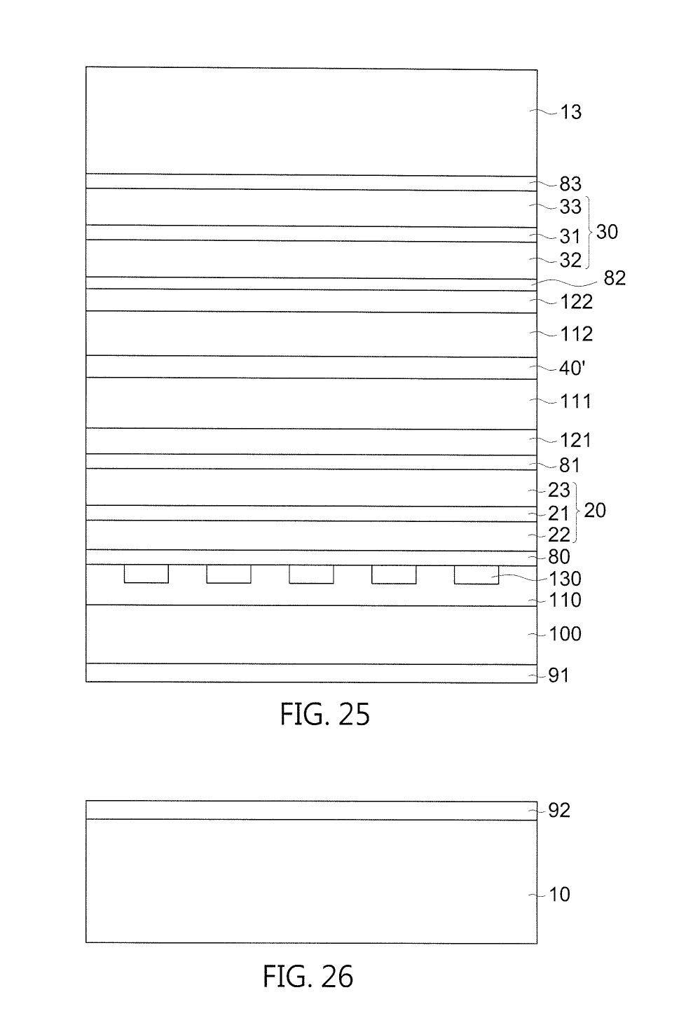

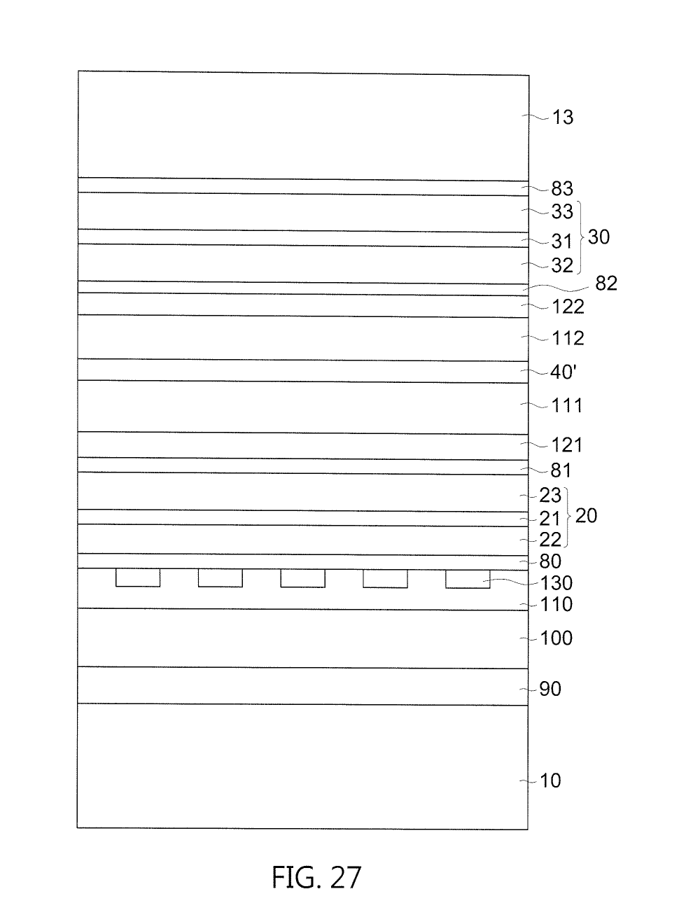

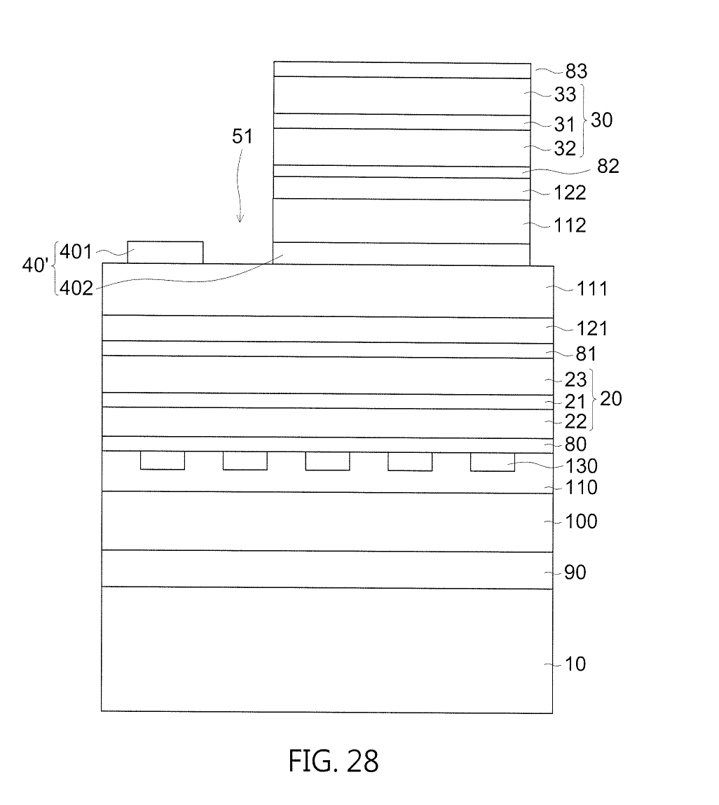

FIG. 21 is a top view of a light-emitting device 5 in accordance with the fifth embodiment of the present application; FIG. 22 is a cross-sectional diagram along a D-D′ line of the light-emitting device 5 in accordance with the fifth embodiment in FIG. 21; FIG. 23 is a top view of the pattern of the first conductive connecting structure 40′ on the lower current spreading oxide layer 111 of the light-emitting device 5 in accordance with the fifth embodiment in FIG. 22. The same reference number given or appeared in FIG. 21 has the same or equivalent meanings as mentioned in the foregoing embodiments. With reference to FIG. 22 and FIG. 23, in the present embodiment, the first conductive connecting structure 40′ comprises a first part 401 and a second part 402. The first part 401 is not covered by the second light-emitting semiconductor stack 30 and is between the first electrode 50 and the first light-emitting semiconductor stack 20. The second part 402 is disposed between the second light-emitting semiconductor stack 30 and the first light-emitting semiconductor stack 20 so as to reflect the second radiation toward the front side of the light-emitting device 5. The first part 401 has a pattern substantially the same as the pattern of the first electrode 50 so as to expose the underlying lower current spreading oxide layer 111. Thus, the first radiation emitted from the first light-emitting semiconductor stack 20 can escape through the exposed lower current spreading oxide layer 111 without shielding by the first conductive connecting structure 40′. As a result, the first radiation and the second radiation both can be extracted from the front side of the light-emitting device 5. With reference to FIG. 23, in one embodiment, the first part 401 is laterally connected to the second part 402 so as to improve current spreading between the first electrode 50 and the second electrode 60. Specifically, the first part 401 has a body part 401a arranged at a corner from a top view and multiple extension parts 401b extending from the body part 401a to the second part 402, The second part 402 has a pattern substantially the same as the pattern of the second light-emitting semiconductor stack 30. In the present embodiment, the second part 402 is a triangle. Preferably, the substrate 10 has a first area, and the first conductive connecting structure 40′ has a second area of between about 45% and 80% of the first area. That is, the exposed lower current spreading oxide layer 111 has a third area of between about 20% and 55% of the first area. Specifically, the first part 401 has a third area of between about 10% and 30% of the first area, and preferably, between about 15% and 25% of the first area. Because the first conductive connecting structure 40′ has a second area of between about 45% and 80% of the first area of the substrate 10, the first conductive connecting structure 40′ can securely connect the first light-emitting semiconductor stack 20 and the second light-emitting semiconductor stack 30, and the first radiation is able to be extracted from the front side of the light-emitting device 5 at the same time. FIGS. 24 to 28 demonstrate a manufacturing process or fabricating the light-emitting device 5 shown in FIG. 28. The initial steps (i) to (vii) are the same as FIGS. 17 to 19 as mentioned in the foregoing embodiments. Referring to FIG. 24, after the step of bonding the first sub-bonding layer 40′a and the second sub-bonding layer 40′b to form the first conductive connecting structure 40′, the method further comprises steps of: (viii) removing the growth substrate 10′. Referring to FIG. 25, the method further comprises the steps of: (ix) forming a first ohmic contact layer 130 on the first contact layer 80; (x) forming a first current spreading oxide layer 110 on the first ohmic contact layer 130 and covering the first ohmic contact layer 130, (xi) forming a reflector 100 on the first current spreading oxide layer 110; and (xii) forming a third sub-bonding layer 91 comprising metal on the reflector 100. Referring to FIG. 26, the method further comprises steps of: (xiii) providing a substrate 10; (xiv) forming a fourth sub-bonding layer 92 comprising metal on the substrate 10. Referring to FIG. 27, the method further comprises the steps of (xv) connecting the structures as shown in FIG. 25 and FIG. 26 by bonding the third sub-bonding layer 91 and the fourth sub-bonding layer 92 to form the second conductive connecting structure 90. Referring to FIG. 28, The method further comprises steps of: (xvi) removing the growth substrate 13; (xvii) removing a part of the second light-emitting semiconductor stack 30 to form a region 51 exposing a part of the first conductive connecting structure 40′; (xviii) removing a part of the exposed first conductive connecting structure 40′ so as to expose a part of the underlying lower current spreading oxide layer 111, wherein the remained first conductive connecting structure 40′ comprises a first part 401 in the region 51 and a second part 402 between the second light-emitting semiconductor stack 30 and the lower current spreading oxide layer 111; and (xix) forming a first electrode 50, a second electrode 60 and a third electrode 70 to obtain the light-emitting device 5 as shown in FIG. 22. The manufacturing process for fabricating the light-emitting device 5 comprises two bonding steps after forming the first light-emitting semiconductor stack 20 emitting the first radiation with longer dominant wavelength relative to the second dominant wavelength of the second radiation. The bonding steps are performed at two opposite sides of the first light-emitting semiconductor stack 20.

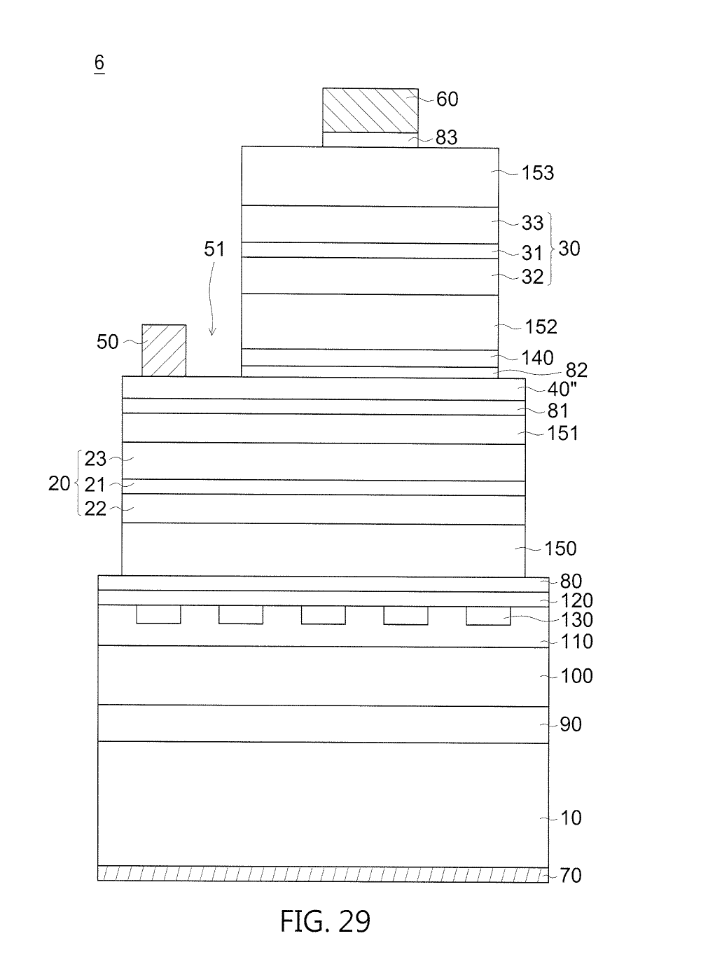

FIG. 29 is a cross-sectional diagram of a light-emitting device 6 in accordance with the sixth embodiment of the present application. The same reference number given or appeared in FIG. 29 has the same or equivalent meanings as mentioned in the foregoing embodiments. In the present embodiment, the first conductive connecting structure 40″ comprises a layer or multiple layers comprising transparent conducive oxide material for connecting the first light-emitting semiconductor stack 20 and the second light-emitting semiconductor stack 30. The light-emitting device 6 comprises a Distributed Bragg reflector 140 between the second light-emitting semiconductor stack 30 and the third contact layer 82. The Distributed Bragg reflector 140 is electrically conductive and comprises alternate first semiconductor sub-layers and second semiconductor sub-layers, wherein the refractive index and the thickness of the first semiconductor sub-layers are different from that of the second semiconductor sub-layers. The Distributed Bragg reflector 140 are designed to have a higher reflectivity to the second dominant wavelength than to the first dominant wavelength by tuning the materials and each thickness of the first sub-semiconductor layers and the second sub-semiconductor layers, and by tuning the pair numbers of the Distributed Bragg reflector 140, wherein one first sub-semiconductor layer and one second sub-semiconductor layer that are laminated are considered as a pair. That is to say, the Distributed Bragg reflector 140 reflects more second radiation than the first radiation. Specifically, the difference between the reflectivity of the Distributed Bragg reflector 140 to the first dominant wavelength and the reflectivity to the second dominant wavelength is greater than 30%, and preferably greater than 50%. In the present embodiment, the Distributed Bragg reflector 140 is a p-type semiconductor. Besides, the transverse width of the Distributed Bragg reflector 140 is less than the transverse width of the first light-emitting semiconductor stack 20, and less than the transverse width of the first conductive connecting structure 40″. As a result, the region 51 where the first electrode 50 is disposed is devoid of the Distributed Bragg reflector 140. Therefore, some of the first radiation emitted from the first active layer 21 escapes from the region 51 and does not pass through the Distributed Bragg reflector 140. Besides, the distance between the Distributed Bragg reflector 140 and the second active layer 31 can be designed as described in U.S. patent application Ser. No. 14/625,156, “LIGHT-EMITTING DIODE,” filed Feb. 18, 2015. In one embodiment, the Distributed Bragg reflector 140 can be grown on the second light-emitting semiconductor stack 30 by epitaxy method. The material of the Distributed Bragg reflector 140 comprises a Group III-V semiconductor material, such as AlₓGa₍₁₋ₓ₎As/Al_{y}Ga_{(1-y)}As (wherein x is different from y) or AlInP/AlGaInP, wherein the content of Al and Ga and the content of Al and In can be adjusted for reflecting a predetermined wavelength range. In one embodiment, The material of the Distributed Bragg reflector 140 comprises AlₓGa₍₁₋ₓ₎As/Al_{y}Ga_{(1-y)}As or AlInP/Al_{z}In_{(1-z)}GaP, wherein x is between 0.7 and 1 both inclusive, y is between 0.4 and 0.6 both inclusive, and preferably, is between 0.3 and 0.5, and z is between 0.5 and 1 both inclusive for reflecting the second radiation.

In one embodiment, the light-emitting device 6 further comprises a first current spreading semiconductor layer 150 between first contact layer 80 and the first cladding layer 22 for improving current spreading throughout the first light-emitting semiconductor stack 20. In one embodiment, the light-emitting device 6 further comprises a second current spreading semiconductor layer 151 between second contact layer 81 and the second cladding layer 23 for improving current spreading throughout the first light-emitting semiconductor stack 20. In one embodiment, the light-emitting device 6 further comprises a third current spreading semiconductor layer 152 between third contact layer 82 and the third cladding layer 32 for improving current spreading throughout the second light-emitting semiconductor stack 30. In one embodiment, the light-emitting device 1 further comprises a fourth current spreading semiconductor layer 153 between fourth contact layer 83 and the fourth cladding layer 33 for improving current spreading throughout the second light-emitting semiconductor stack 30. The band gap of the first current spreading semiconductor layer 150 and the band gap of the second current spreading semiconductor layer 151 both are higher than the band gap of the first active layer 21. The first current spreading semiconductor layer 150 and the second current spreading semiconductor layer 151 are substantially pervious to the first radiation emitted from the first active layer 21. The band gap of the third current spreading semiconductor layer 152 and the band gap of the fourth current spreading semiconductor layer 153 both are higher than the band gap of the second active layer 31. The third current spreading semiconductor layer 152 and the fourth current spreading semiconductor layer 153 are substantially pervious to the second radiation emitted from the second active layer 31. Preferably, the first, second, third and fourth current spreading semiconductor layers 150,151,152,153 each has a thickness preferably not less than 1 μm, and more preferably not greater than 10 μm. The first, second, third and fourth current spreading semiconductor layers 150,151,152,153 comprise a Group III-V semiconductor material, such as AlGaAs, GaP, AlGaInP. The first, second, third and fourth current spreading semiconductor layers 150,151,152,153 can be also applied to the foregoing embodiment.

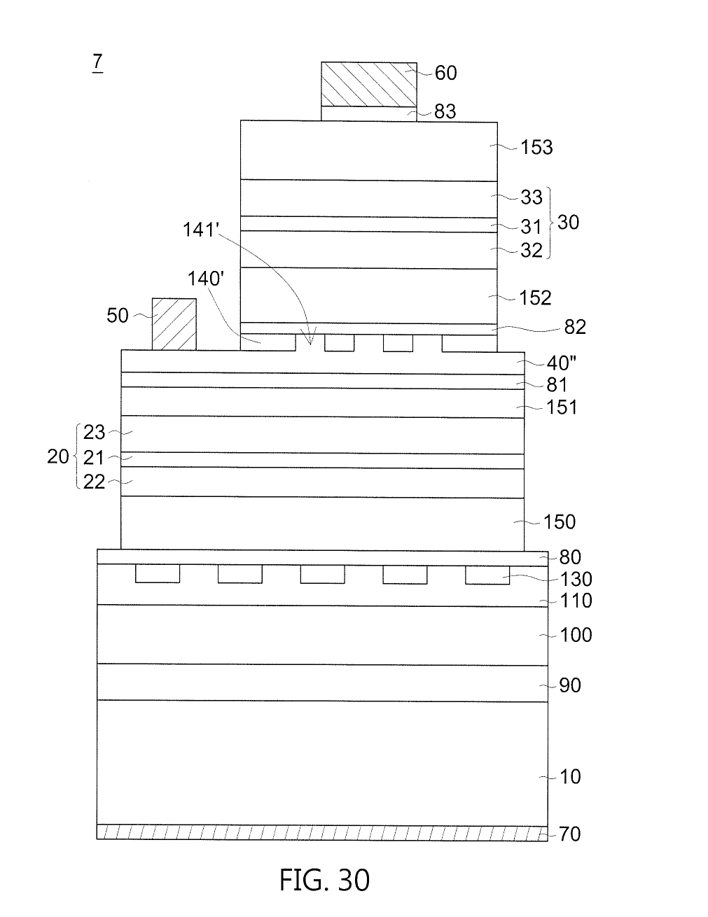

FIG. 30 is a cross-sectional diagram of a light-emitting device 7 in accordance with the seventh embodiment of the present application. The same reference number given or appeared in FIG. 30 has the same or equivalent meanings as mentioned in the foregoing embodiments. In the present embodiment, the difference is that the Distributed Bragg reflector 140′ comprises an electrically insulating material and a pattern comprising multiple openings 141′ that are regularly arranged in a two-dimensional array. In one embodiment, the substrate 10 has a first area, the area of the multiple openings are less than 30% of the first area, and preferably, between about 3% and 25% of the first area. The first conductive connecting structure 40″ covers the Distributed Bragg reflector 140′ and physically contacts the third contact layer 82 by filling into the multiple openings 141′ of the Distributed Bragg reflector 140′. The Distributed Bragg reflector 140′ comprises an polymer material comprising polyimide (PI), benzocyclobutene (BCB), prefluorocyclobutane (PFCB), epoxy, Sub, acrylic resin, cyclic olefin polymers (COC), polymethylmethacrylate (PMMA), polyethylene terephthalate (PET), polycarbonate (PC), polyetherimide, or fluorocarbon polymer. glass In one embodiment, the Distributed Bragg reflector 140′ comprises an oxide material comprising MgO, Al₂O₃, SiO₂, TiO₂, SiNₓ, Nb₂O₅, spin-on glass material or tetraethyl orthosilicate (TEOS).

In one embodiment, the first dominant wavelength is about 940±100 nm, and the second dominant wavelength is about 660±100 nm. The first radiation and the second radiation are both incoherent. Therefore, the light-emitting device has a far field angle greater than 70 degrees. In one embodiment, the far field angle is greater than 90 degrees.

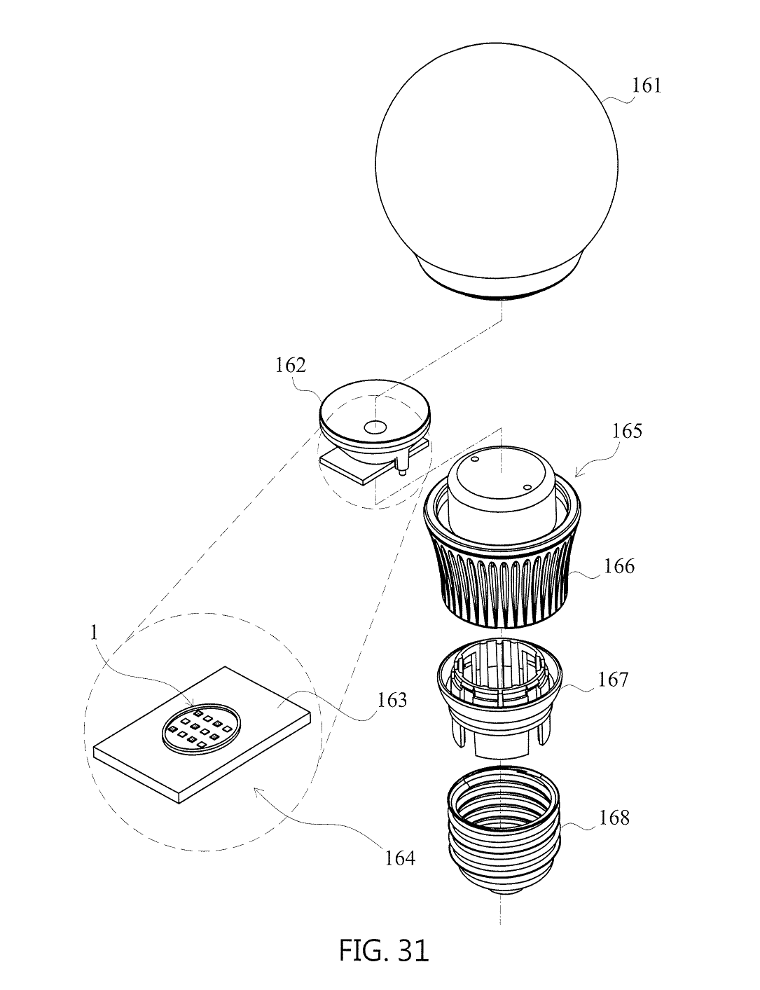

The light-emitting devices as mentioned above are able to combine with other downstream structures to form a light bulb. FIG. 31 is an exploded view of a light bulb in accordance with the present application. The light bulb comprises a lamp 161, a lens 162 disposed in the lamp 161, a lighting module 164 disposed under the lens 162, a lamp holder 165 comprising a heat sink 166, wherein the lighting module 164 is used for holding the lighting module 164, a connecting part 167, and an electrical connector 168, wherein the connecting part 167 connects the lamp holder 165 to the electrical connector 168. The lighting module 164 comprises a carrier 163 and multiple light-emitting devices 1 of any one of the embodiments as mentioned above, wherein the multiple light-emitting devices 1 are on the carrier 163.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

1. A light-emitting device, comprising:
a first light-emitting semiconductor stack having a first transverse width and comprising a first active layer, wherein the first active layer emits a first radiation of a first dominant wavelength during operation;
a second light-emitting semiconductor stack having a second transverse width less than the first transverse width and comprising a second active layer on the first light-emitting semiconductor stack, wherein the second active layer emits a second radiation of a second dominant wavelength shorter than the first dominant wavelength during operation; and
a first conductive connecting structure between the first light-emitting semiconductor stack and the second light-emitting semiconductor stack,
wherein the first conductive connecting structure comprises multiple layers having refractive indices different from one another, and the refractive indices of the multiple layers of the first conductive connecting structure are decreased as the distance between the layer of the first conductive connecting structure and the first light-emitting semiconductor stack increases, wherein one of the multiple layers having a refractive index between 1.35 and 1.48.

2. The light-emitting device according to claim 1, wherein the material of the first conductive connecting structure comprises transparent conducive material.

3. (canceled)

4. The light-emitting device according to claim 1, wherein the difference of the refractive indices of two adjacent layers of the multiple layers is not less than 0.15.

5. The light-emitting device according to claim 1, further comprising an ohmic contact layer formed in the first conductive connecting structure, wherein one of the multiple layers with the lowest refractive index comprises a pattern comprising multiple openings, and the ohmic contact layer comprises a pattern complementary to the pattern of the layer with the lowest refractive index.

6. The light-emitting device according to claim 1, further comprising a current spreading semiconductor layer between the second light-emitting semiconductor stack and the first conductive connecting structure, wherein the current spreading semiconductor layer comprises a roughened surface facing the first conductive connecting structure.

7. The light-emitting device according to claim 6, wherein one of the multiple layers with the lowest refractive index comprises a pattern comprising multiple openings, and the roughened surface is substantially consistent with the pattern of the layer with the lowest refractive index.

8. The light-emitting device according to claim 1, further comprising a first electrode on the first conductive connecting structure and commonly electrically connected to the first light-emitting semiconductor stack and the second light-emitting semiconductor stack and a second electrode on the second light-emitting semiconductor stack.

9. The light-emitting device according to claim 8, further comprising an ohmic contact layer formed in the first conductive connecting structure and physically contacts the first electrode.

10. The light-emitting device according to claim 9, wherein in a cross-sectional view of the light-emitting device, the first conductive structure has a third maximum transverse width and the ohmic contact layer has a width less than the third maximum transverse width.

11. The light-emitting device according to claim 9, further comprising a substrate under the first light-emitting semiconductor stack, wherein the substrate has a first area and the ohmic contact layer has a second area of 3% to 25% of the first area.

12. The light-emitting device according to claim 2, wherein the first conductive connecting structure has a higher transmittance to the first dominant wavelength than to the second dominant wavelength.

13-15. (canceled)

16. The light-emitting device according to claim 1, further comprising a substrate under the first light-emitting semiconductor stack and a second conductive connecting structure between the substrate and the first light-emitting semiconductor stack.

17. The light-emitting device according to claim 1, further comprising a Distributed Bragg reflector between the first conductive connecting structure and the second light-emitting semiconductor stack, wherein the Distributed Bragg reflector has a higher transmittance to the first dominant wavelength than to the second dominant wavelength.

18. The light-emitting device according to claim 1, wherein the first radiation has a far field angle greater than 70 degrees and the second radiation has a far field angle greater than 70 degrees.

19. The light-emitting device according to claim 1, wherein the first light-emitting semiconductor stack and the second light-emitting semiconductor stack can be independently controlled during operation.

20. The light-emitting device according to claim 1, wherein the first conductive connecting structure has a third transverse width substantially the same as the first transverse width.

21. The light-emitting device according to claim 1, wherein a layer of the first conductive connecting structure is lattice-mismatched to the first active layer and to the second active layer.

22. A light-emitting device, comprising:
a first light-emitting semiconductor stack having a first transverse width and comprising a first active layer, wherein the first active layer emits a first radiation of a first dominant wavelength during operation;
a second light-emitting semiconductor stack having a second transverse width less than the first transverse width and comprising a second active layer on the first light-emitting semiconductor stack, wherein the second active layer emits a second radiation of a second dominant wavelength shorter than the first dominant wavelength during operation;
a first conductive connecting structure between the first light-emitting semiconductor stack and the second light-emitting semiconductor stack;
a first electrode on the first conductive connecting structure and electrically connected to the first light-emitting semiconductor stack and the second light-emitting semiconductor stack; and
a second electrode on the second light-emitting semiconductor stack,
wherein the first conductive connecting structure comprises metal material.

23. The light-emitting device according to claim 22, wherein the top surface of the first conductive connecting structure between the first light-emitting semiconductor stack and the second light-emitting semiconductor stack comprises a first part not covered by the second active layer and a second part interposed between the second active layer and the first active layer.

24. The light-emitting device according to claim 22, further comprising a substrate under the first light-emitting semiconductor stack, wherein the substrate has a first area, the first conductive connecting structure has a second area of 45% to 80% of the first area.
